(19) United States
(12) Patent Application Publication
(10) Pub. No.: US 2025/0167761 A1
(43) Pub. Date: May 22, 2025

(54) ELASTIC WAVE DEVICE AND COMMUNICATION APPARATUS

(71) Applicant: KYOCERA Corporation, Kyoto-shi, Kyoto (JP)

(72) Inventor: Soichiro NOZOE, Kyoto-shi (JP)

(73) Assignee: KYOCERA Corporation, Kyoto-shi, Kyoto (JP)

(21) Appl. No.: 18/839,499

(22) PCT Filed: Jan. 31, 2023
(86) PCT No.: PCT/JP2023/003020

§ 371 Date: Aug. 19, 2024

(30) Foreign Application Priority Data
Feb. 22, 2022 (JP) 2022-026021

(51) Int. Cl. H03H 9/25; H03H 9/145

(52) U.S. Cl. CPC H03H 9/25; H03H 9/145

(57) ABSTRACT

To reduce spurious components of an elastic wave device using a Lamb wave. In the elastic wave device using a Lamb wave, at least a part of an electrode is embedded in a piezoelectric body.

### TECHNICAL FIELD

The present disclosure relates to an elastic wave device and a communication apparatus.

### BACKGROUND OF INVENTION

Patent Document 1 discloses an elastic wave device using a Lamb wave, in particular, an elastic wave device in which an A₁ mode is an antisymmetric mode.

For example, Patent Documents 2 to 12 disclose an elastic wave device having a configuration in which an electrode is embedded in a piezoelectric body.

### CITATION LIST

### Patent Literature

Patent Document 1: WO 2012/086441
Patent Document 2: WO 2020/204045
Patent Document 3: JP 2019-062441 A
Patent Document 4: WO 2014/054580
Patent Document 5: WO 2012/099083
Patent Document 6: WO 2009/090714
Patent Document 7: WO 2006/011417
Patent Document 8: WO 2010/058570
Patent Document 9: WO 2010/058544
Patent Document 10: WO 2007/080734
Patent Document 11: JP 2013-066250 A
Patent Document 12: JP 2013-214789 A

### SUMMARY

An elastic wave device according to an aspect of the present disclosure uses a Lamb wave, including a piezoelectric body and an electrode, at least a part of the electrode being embedded in the piezoelectric body.

An elastic wave device according to an aspect of the present disclosure includes a piezoelectric body and an electrode, the piezoelectric body is formed with a groove, the electrode is an IDT electrode and includes electrode fingers, and at least a part of the electrode fingers is located inside the groove.

### BRIEF DESCRIPTION OF THE DRAWINGS

FIG. 1 is a cross-sectional view illustrating a schematic configuration of an elastic wave device according to a first embodiment of the present disclosure.

FIG. 2 is a cross-sectional view illustrating a schematic configuration of an elastic wave device according to a comparative embodiment of the present disclosure.

FIG. 3 is a table showing various configurations of an embedded structure A and a normal structure A.

FIG. 4 is a graph showing the relationship of Δf with respect to θ in the embedded structure A and the normal structure A, and a table summarizing a center value of θ and a maximum value of Δf.

FIG. 5 is a graph showing the relationship of a phase with respect to a frequency in the embedded structure A and the normal structure A.

FIG. 6 is four types of graphs showing the relationship of impedance with respect to frequency in the embedded structure A.

FIG. 7 is a graph showing the relationship of Δf with respect to φ in the embedded structure A.

FIG. 8 is a graph showing the relationship of Δf with respect to ψ in the embedded structure A.

FIG. 9 is four types of graphs showing the relationship of impedance with respect to frequency in the embedded structure A.

FIG. 10 is a table showing various configurations of an embedded structure B and a normal structure B.

FIG. 11 is a graph showing the relationship of Δf with respect to θ in the embedded structure B and the normal structure B, and a table summarizing a center value of θ and a maximum value of Δf.

FIG. 12 is a graph showing the relationship of phase with respect to frequency in the embedded structure B and the normal structure B.

FIG. 13 is a graph showing the relationship of Δf with respect to φ in the embedded structure B.

FIG. 14 is a graph showing the relationship of Δf with respect to ψ in the embedded structure B.

FIG. 15 is a table summarizing ranges and center values of φ, θ, and ψ derived for each material of a piezoelectric body.

FIG. 16 is a graph showing the relationship of phase with respect to frequency in a membrane embedded structure A and a membrane normal structure A.

FIG. 17 is a graph showing the relationship of phase with respect to frequency in a membrane embedded structure B and a membrane normal structure B.

FIG. 18 shows Equations (1) to (6).

FIG. 19 is three types of graphs related to Equation (7) to be described below.

FIG. 20 shows Equation (7).

FIG. 21 is three types of graphs related to Equation (8) to be described below.

FIG. 22 shows Equation (8).

FIG. 23 illustrates three types of structures of the elastic wave device.

FIG. 24 is four types of graphs showing the relationship of phase and frequency in structures of three types of elastic wave devices.

FIG. 25 is a cross-sectional view of a first simulation structure.

FIG. 26 is a table showing various configurations of the first simulation structure used for simulation of the positional relationship between an upper surface of an electrode and an upper surface of the piezoelectric body.

FIG. 27 is a diagram for explaining the definition of a variable Y in a convex structure.

FIG. 28 is a graph showing the relationship of phase with respect to frequency in a convex structure in which a material of the piezoelectric body is lithium niobate, together with a cross-sectional view of the corresponding piezoelectric body and electrode.

FIG. 29 is a graph showing the relationship of Δf with respect to a value of Y in a convex structure in which a material of the piezoelectric body is lithium niobate.

FIG. 30 is a graph showing the relationship of resonance frequency fr with respect to a value of Y in a convex structure in which a material of the piezoelectric body is lithium niobate.

FIG. 31 is a graph showing the relationship of phase with respect to frequency in a convex structure in which a material of the piezoelectric body is lithium tantalate, together with a cross-sectional view of the corresponding piezoelectric body and electrode.

FIG. 32 is a graph showing the relationship of Δf with respect to a value of Y in a convex structure in which a material of the piezoelectric body is lithium tantalate.

FIG. 33 is a graph showing the relationship of a resonance frequency fr with respect to a value of Y in a convex structure in which a material of the piezoelectric body is lithium tantalate.

FIG. 34 is a diagram for explaining the definition of a variable X in a concave structure.

FIG. 35 is a graph showing the relationship of phase with respect to frequency in a concave structure in which a material of the piezoelectric body is lithium niobate, together with a cross-sectional view of the corresponding piezoelectric body and electrode.

FIG. 36 is a graph showing the relationship of Δf with respect to a value of X in a concave structure in which a material of the piezoelectric body is lithium niobate.

FIG. 37 is a graph showing the relationship of a resonance frequency fr with respect to a value of X in a concave structure in which a material of the piezoelectric body is lithium niobate.

FIG. 38 is a graph showing the relationship of phase with respect to frequency in a concave structure in which a material of the piezoelectric body is lithium tantalate, together with a cross-sectional view of the corresponding piezoelectric body and electrode.

FIG. 39 is a graph showing the relationship of Δf with respect to a value of X in a concave structure in which the material of the piezoelectric body is lithium tantalate.

FIG. 40 is a graph showing the relationship of a resonance frequency fr with respect to a value of X in a concave structure in which a material of the piezoelectric body is lithium tantalate.

FIG. 41 is a cross-sectional view of a second simulation structure.

FIG. 42 is a table showing various configurations of the second simulation structure used for simulation of a thickness of an electrode.

FIG. 43 is cross-sectional views of a piezoelectric body and an electrode for explaining the expression of the thickness of the electrode by a percentage of a thickness of the piezoelectric body.

FIG. 44 is a graph showing the relationship of Δf with respect to thickness of the electrode when a material of the piezoelectric body is lithium tantalate.

FIG. 45 is a graph showing the relationship of Δf with respect to thickness of the electrode when a material of the piezoelectric body is lithium niobate.

FIG. 46 is a graph showing the relationship of impedance with respect to frequency when a material of the piezoelectric body is lithium niobate.

FIG. 47 is a graph showing the relationship of phase with respect to frequency when a material of the piezoelectric body is lithium niobate.

FIG. 48 is another graph showing the relationship of phase with respect to frequency when a material of the piezoelectric body is lithium niobate.

FIG. 49 is a table summarizing advantageous configurations of a thicknesses of the electrode.

FIG. 50 is a graph showing the relationship of Δf with respect to Duty when a material of the piezoelectric body is lithium tantalate.

FIG. 51 is a graph showing the relationship of Δf with respect to Duty when a material of the piezoelectric body is lithium niobate.

FIG. 52 is a table summarizing advantageous configurations of Duty.

FIG. 53 is a cross-sectional view of a third simulation structure.

FIG. 54 is a table showing various configurations of the third simulation structure used for simulation of a derivative structure.

FIG. 55 is a graph showing the relationship of phase with respect to frequency when a material of the piezoelectric body is lithium niobate.

FIG. 56 is a graph showing the relationship of phase with respect to frequency when a material of the piezoelectric body is lithium tantalate.

FIG. 57 is a cross-sectional view of a fourth simulation structure.

FIG. 58 is a table showing various configurations of the fourth simulation structure used for the simulation of a derivative structure.

FIG. 59 is cross-sectional views of back surface embedding and full surface embedding.

FIG. 60 is a graph showing the relationship of Δf with respect to θ in back surface embedding in which a material of the piezoelectric body is lithium niobate.

FIG. 61 is a graph showing the relationship of Δf with respect to θ in back surface embedding in which a material of the piezoelectric body is lithium tantalate.

FIG. 62 is a table summarizing advantageous configurations of θ in back surface embedding.

FIG. 63 is a graph showing the relationship of Δf with respect to θ in full surface embedding in which a material of the piezoelectric body is lithium niobate.

FIG. 64 is a graph showing the relationship of Δf with respect to θ in full surface embedding in which a material of the piezoelectric body lithium tantalate.

FIG. 65 is a table summarizing advantageous configurations of θ in full surface embedding.

### DESCRIPTION OF EMBODIMENTS

### First Embodiment

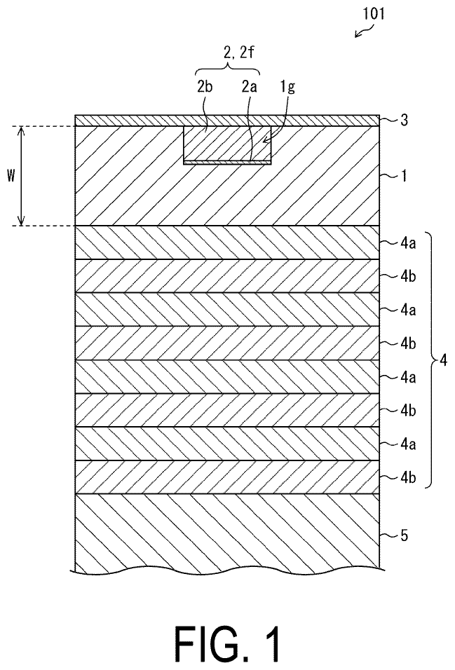

FIG. 1 is a cross-sectional view illustrating a schematic configuration of an elastic wave device 101 according to a first embodiment of the present disclosure.

The elastic wave device 101 is an elastic wave device using a Lamb wave. Specifically, the elastic wave device 101 is an elastic wave device that excites a Lamb wave in a piezoelectric body 1. The elastic wave device 101 may use a A₁ mode, which is an antisymmetric mode. Specifically, the elastic wave device 101 may excite the A₁ mode in the piezoelectric body 1.

The Lamb wave and the A₁ mode are additionally described. A plate wave is classified into a Lamb wave whose vibration plane is perpendicular to a plate surface and an SH wave whose vibration plane is parallel to a plate surface. The Lamb wave is classified into an S mode being a symmetric mode and an A mode being an antisymmetric mode. The A₁ mode corresponds to a first-order antisymmetric mode.

The elastic wave device 101 includes the piezoelectric body 1, electrodes 2, a protective film 3, a multilayer film 4, and a support substrate 5. At least a part of the electrode 2 is embedded in the piezoelectric body 1. The protective film 3 covers the piezoelectric body 1 and the electrode 2. The multilayer film 4 is disposed under the piezoelectric body 1 and the electrode 2.

The piezoelectric body 1 may be made of lithium tantalate or lithium niobate. Lithium tantalate may be represented by LiTaO₃ and is hereinafter also referred to as LT. Lithium niobate may be represented by LiNbO₃ and is hereinafter also referred to as LN. The piezoelectric body 1 is formed with a groove for embedding the electrode 2, and the electrode 2 is formed in the groove.

The electrode 2 may include aluminum. A side surface of the electrode 2 is in contact with the piezoelectric body 1.

The electrode 2 may be a so-called interdigital transducer (IDT) electrode. One of a plurality of electrode fingers constituting the IDT electrode may be interpreted as an electrode finger 2f illustrated in FIG. 1. In the elastic wave device 101, an upper surface of the electrode 2 is flush with an upper surface of the piezoelectric body 1. The upper surface of the electrode 2 and the upper surface of the piezoelectric body 1 may not be flush with each other. The upper surface of the electrode 2 may be convex or concave with respect to the upper surface of the piezoelectric body 1. The inventor of the present application has confirmed the effect of reducing a spurious component by embedding at least a part of the electrode 2 even when the upper surface of the electrode 2 is convex or concave.

The piezoelectric body 1 is formed with a groove 1g. When the electrode 2 is an IDT electrode and includes the electrode finger 2f, at least a part of the electrode finger 2f is located inside the groove 1g.

The electrode 2 includes a single layer or a layered structure of a plurality of layers. The plurality of layers include a first layer 2a and a second layer 2b disposed on the first layer 2a. Alternatively, the electrode 2 may include a third layer or more layers. The first layer 2a may be made of titanium. Various conductive materials are used for the first layer 2a to improve adhesion between the electrode 2 and the piezoelectric body 1. The second layer 2b may be made of aluminum.

A side surface of the uppermost layer of the plurality of layers, that is, a side surface of the second layer 2b is in contact with the piezoelectric body 1. Alternatively, a side surface of the thickest layer of the plurality of layers may be in contact with the piezoelectric body 1. The first layer 2a may cover the bottom surface and the side surface of the second layer 2b. Another layer may be interposed between the side surface of the second layer 2b and the side surface of the piezoelectric body 1.

The piezoelectric body 1 does not need to be present on the bottom surface side of the electrode 2. The bottom surface of the electrode 2 may be in contact with the multilayer film 1. That is, the first layer 2a may be in contact with a low acoustic impedance layer of the multilayer film 1. In the case of a membrane structure to be described below, the bottom surface of the electrode 2 may be exposed to a space.

The protective film 3 may be SiO₂, or an insulating material generally used as a protective film may be used as desired.

The multilayer film 4 includes a low acoustic impedance layer 4a and a high acoustic impedance layer 4b. The acoustic impedance of the low acoustic impedance layer 4a is lower than the acoustic impedance of the high acoustic impedance layer 4b.

The low acoustic impedance layer 4a and the high acoustic impedance layer 4b are layered in the order of the high acoustic impedance layer 4b and the low acoustic impedance layer 4a from the support substrate 5 side. The multilayer film 4 has one or more layered structures, and has four layered structures in FIG. 1. The piezoelectric body 1 is in contact with the low acoustic impedance layer 4a. A layer using a high acoustic impedance material that is thin enough not to function as a high acoustic impedance layer may be interposed between the piezoelectric body 1 and the low acoustic impedance layer 4a. The low acoustic impedance layer 4a may include SiO₂. The high acoustic impedance layer 4b may include at least one selected from the group consisting of HfO₂, Ta₂O₅, and ZrO₂.

The multilayer film 4 may be an acoustic reflection film. In this case, a Lamb wave propagating from above the elastic wave device 101 is reflected at an interface between the low acoustic impedance layer 4a and the high acoustic impedance layer 4b.

The support substrate 5 is a substrate that supports the piezoelectric body 1, the electrode 2, the protective film 3, and the multilayer film 4 from below. The support substrate 5 may be made of silicon, or various materials such as sapphire and glass may be used.

The piezoelectric body 1 is formed relatively thin. A thickness W of the piezoelectric body 1 may be 1.5 times or less or from 0.3 times to 0.6 times or less a pitch of the electrode 2 to be described below.

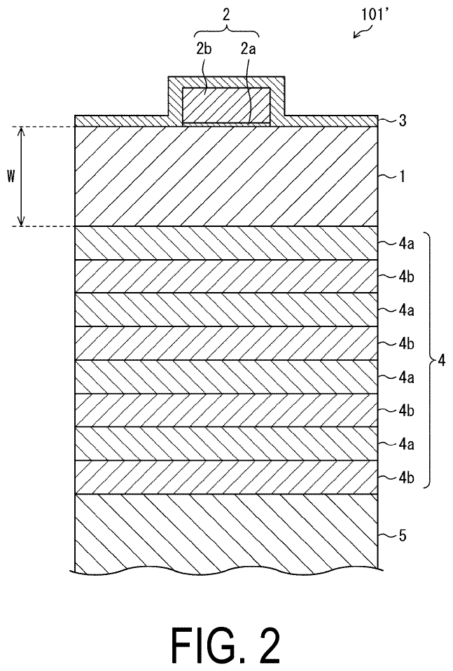

FIG. 2 is a cross-sectional view of a schematic configuration of an elastic wave device 101′ according to a comparative embodiment of the present disclosure. The schematic configuration of the elastic wave device 101′ is different from the schematic configuration of the elastic wave device 101 in that the electrode 2 is not embedded in the piezoelectric body 1, and is the same as the schematic configuration of the elastic wave device 101 otherwise. That is, in the elastic wave device 101′, the piezoelectric body 1 is formed with no groove for embedding the electrode 2, and the electrode 2 is formed on the upper surface of the piezoelectric body 1 having a plate shape.

A first example of the elastic wave device 101 is referred to as an “embedded structure A”, and a first example of the elastic wave device 101′ is referred to as a “normal structure A”.

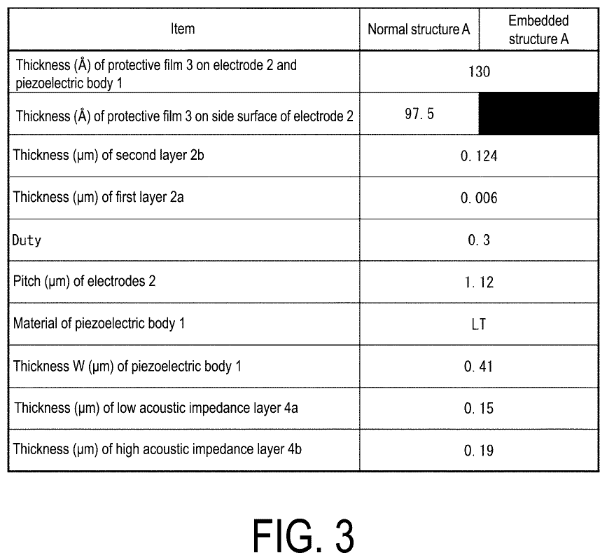

FIG. 3 is a table showing various configurations of the embedded structure A and the normal structure A. The electrode 2 is an IDT electrode. A material of the protective film 3 is SiO₂. A material of the second layer 2b is aluminum. A material of the first layer 2a is titanium. A material of the low acoustic impedance layer 4a is SiO₂. A material of the high acoustic impedance layer 4b is HfO₂.

The pitch of the electrodes 2 is a pitch between the electrode finger 2f of the electrode 2 and another electrode finger (not illustrated) adjacent to the electrode finger 2f. Duty is a value obtained by dividing the width of the electrode finger 2f of the electrode 2 by the pitch of the electrodes 2.

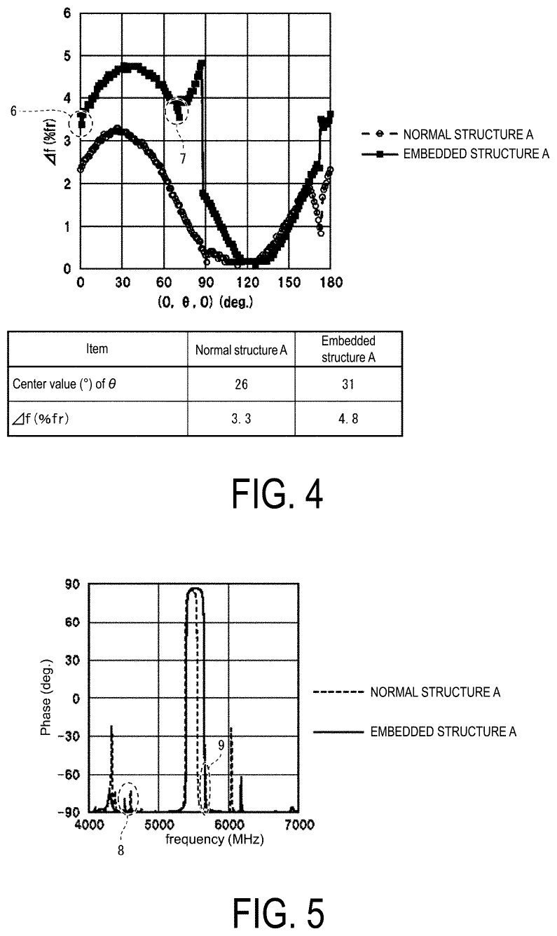

FIG. 4 is a graph showing the relationship of Δf shown on the vertical axis and expressed in units of % fr with respect to θ shown on the horizontal axis and expressed in units of deg, and a table summarizing a center value of θ and a maximum value of Δf in the embedded structure A and the normal structure A. The graph of FIG. 4 shows the relationship when φ=0° and ψ=0°.

Euler angles of the piezoelectric body 1 are represented by (φ, θ, ψ). φ is φ in the Euler angles (φ, θ, ψ) of the piezoelectric body 1, θ is θ in the Euler angles (φ, θ, ψ) of the piezoelectric body 1, and ψ is ψ in the Euler angles (φ, θ, ψ) of the piezoelectric body 1.

Δf is a difference between a resonant frequency and an anti-resonant frequency in the elastic wave device. The unit “% fr” represents the difference as a percentage with respect to the resonant frequency of the elastic wave device.

The center value is a value at which the value of Δf is maximum.

According to the graph of FIG. 4, when θ is from 0° to 90° in the embedded structure A, Δf of the embedded structure A generally exceeds 3.3% fr, which is the maximum value of Δf of the normal structure A. It can be seen that a bandwidth of the embedded structure A is wider than that of the normal structure A.

According to the characteristics of the embedded structure A, spurious components 6 and 7 occur at the point of θ=0° and the point of θ=70°, respectively. In the embedded structure A, it can be seen that θ may be in the range of 1 to 69°.

FIG. 5 is a graph showing the relationship of phase shown on the vertical axis and expressed in units of deg with respect to frequency shown on the horizontal axis and expressed in units of MHz in the embedded structure A and the normal structure A. FIG. 5 illustrates the relationship when θ=31°.

In the graph of FIG. 5, when the characteristics of the embedded structure A are compared with the characteristics of the normal structure A, spurious components 8 and 9 do not exist in the characteristics of the embedded structure A, and exist only in the characteristics of the normal structure A. It can be seen that the spurious components are reduced in the embedded structure A as compared with the normal structure A.

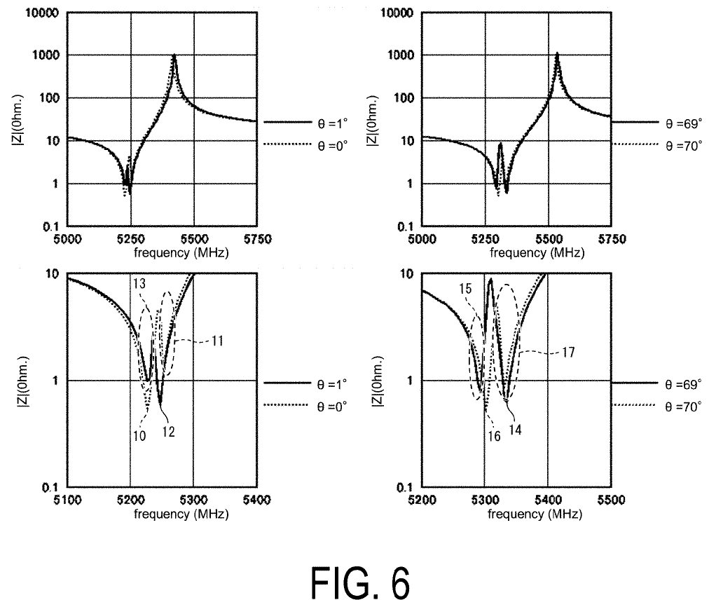

FIG. 6 is four types of graphs showing the relationship of impedance shown on the vertical axis and expressed in units of ohm with respect to frequency shown on the horizontal axis and expressed in units of MHz in the embedded structure A. The four types of graphs are as follows.

Upper left: Characteristics of θ=0° and θ=1° when the frequency range is 5000 to 5750 MHz.

Lower left: Characteristics of θ=0° and θ=1° when the frequency range is 5100 to 5400 MHZ.

Upper right: Characteristics of θ=69° and θ=70° when the frequency range is 5000 to 5750 MHz.

Lower right: Characteristics of θ=69° and θ=70° when the frequency range is 5200 to 5500 MHz.

A minimum point of the impedance is defined as a resonance frequency fr. According to the lower left graph of FIG. 6, when θ=0°, the resonance frequency fr is represented by reference numeral 10, and a spurious component 11 occurs. According to the lower left graph of FIG. 6, when θ=1°, the resonance frequency fr is represented by reference numeral 12, and a spurious component 13 occurs. According to the lower right graph of FIG. 6, when θ=69°, the resonance frequency fr is represented by reference numeral 14, and a spurious component 15 occurs. According to the lower right graph of FIG. 6, when θ=70°, the resonance frequency fr is represented by reference numeral 16, and a spurious component 17 occurs.

The pass/fail criterion for the characteristics of the embedded structure A is that the peak frequency of the spurious component is lower than the resonance frequency fr. According to FIG. 6, the peak frequency of the spurious component is lower than the resonance frequency fr at θ=1° and θ=69°, whereas the peak frequency of the spurious component is higher than the resonance frequency fr at θ=0° and θ=70°.

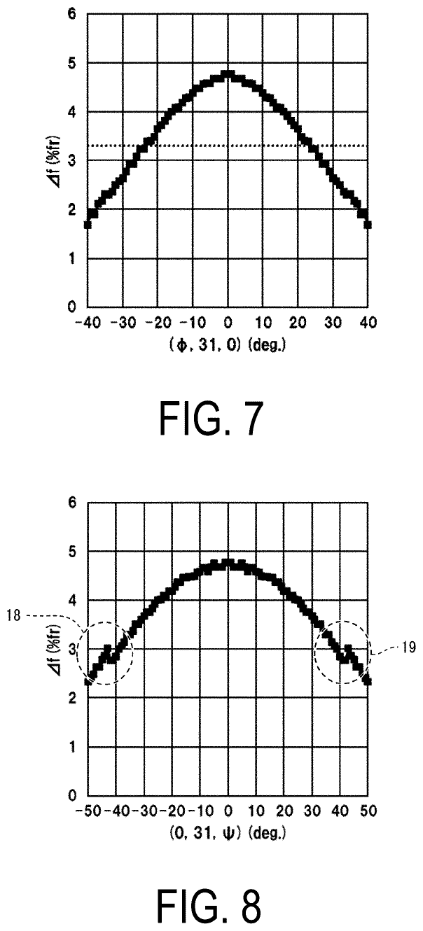

FIG. 7 is a graph showing the relationship of Δf shown on the vertical axis and expressed in units of % fr with respect to φ shown on the horizontal axis and expressed in units of deg in the embedded structure A. The graph of FIG. 7 shows the relationship when θ=31° and ψ=0°.

According to FIG. 7, when φ=−23° or more and φ=23° or less, Δf of the embedded structure A exceeds 3.3% fr, which is the maximum value of Δf of the normal structure A. In the embedded structure A, it can be seen that φ may be in the range of −23 to 23°. According to FIG. 7, the center value of q in the embedded structure A is 0°.

FIG. 8 is a graph showing the relationship of Δf shown on the vertical axis and expressed in units of % fr with respect to φ shown on the horizontal axis and expressed in units of deg in the embedded structure A. The graph of FIG. 8 shows the relationship when φ=0° and θ=31°.

According to FIG. 8, spurious components 18 and 19 occur at the point of ψ=−43° and the point of ψ=43°, respectively. In the embedded structure A, it can be seen that ψ may be in the range of −42 to 42°. According to FIG. 8, the center value of ψ in the embedded structure A is 0°.

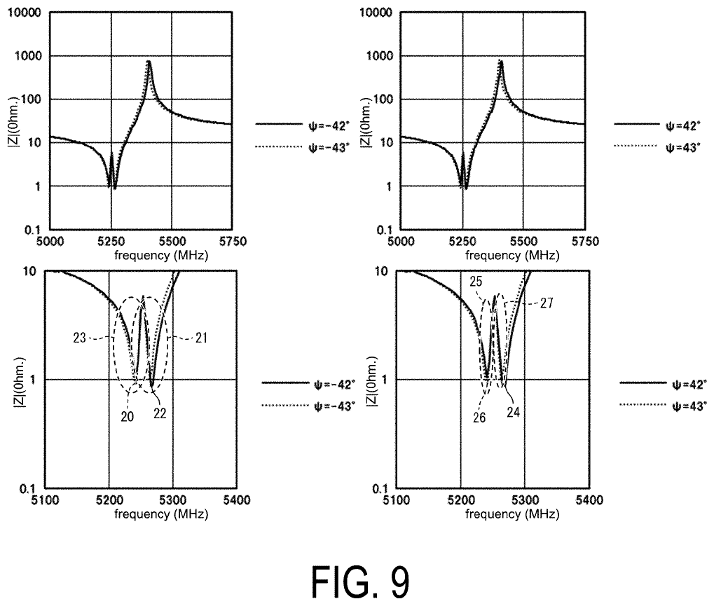

FIG. 9 is four types of graphs showing the relationship of impedance shown on the vertical axis and expressed in units of ohm with respect to frequency shown on the horizontal axis and expressed in units of MHz in the embedded structure A. The four types of graphs are as follows.

Upper left: Characteristics of ψ=−43° and ψ=−42° when the frequency range is 5000 to 5750 MHz.

Lower left: Characteristics of ψ=−43° and ψ=−42° when the frequency range is 5100 to 5400 MHz.

Upper right: Characteristics of ψ=42° and ψ=43° when the frequency range is 5000 to 5750 MHz.

Lower right: Characteristics of ψ=42° and ψ=43° when the frequency range is 5100 to 5400 MHz.

According to the lower left graph of FIG. 9, when ψ=−43°, the resonance frequency fr is represented by reference numeral 20, and a spurious component 21 occurs. According to the lower left graph of FIG. 9, when ψ=−42°, the resonance frequency fr is represented by reference numeral 22, and a spurious component 23 occurs. According to the lower right graph of FIG. 9, when ψ=42°, the resonance frequency fr is represented by reference numeral 24, and a spurious component 25 occurs. According to the lower right graph of FIG. 9, when ψ=43°, the resonance frequency fr is represented by reference numeral 26, and a spurious component 27 occurs.

The pass/fail criterion for the characteristics of the embedded structure A is that the peak frequency of the spurious component is lower than the resonance frequency fr. According to FIGS. 9, at ψ=−42° and ψ=42°, the peak frequency of the spurious component is lower than the resonance frequency fr, while at ψ=−43° and ψ=43°, the peak frequency of the spurious component is higher than the resonance frequency fr.

A second example of the elastic wave device 101 is referred to as an “embedded structure B”, and a second example of the elastic wave device 101′ is referred to as a “normal structure B”.

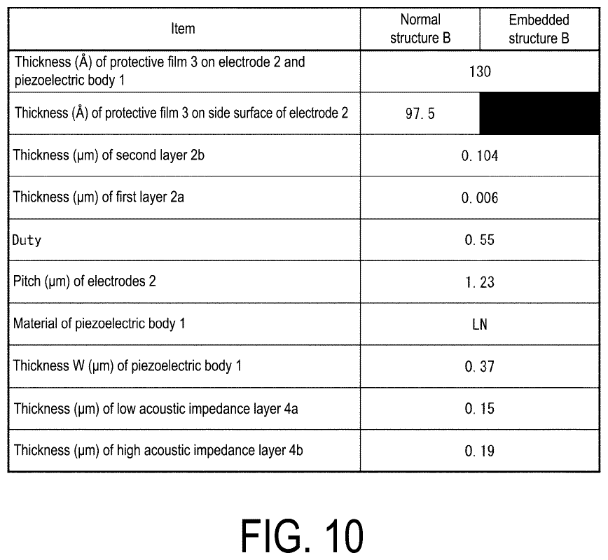

FIG. 10 is a table showing various configurations of the embedded structure B and the normal structure B. The electrode 2 is an IDT electrode. A material of the protective film 3 is SiO₂. A material of the second layer 2b is aluminum. A material of the first layer 2a is titanium. A material of the low acoustic impedance layer 4a is SiO₂. A material of the high acoustic impedance layer 4b is HfO₂. Various definitions in FIG. 10 are the same as various definitions in FIG. 3.

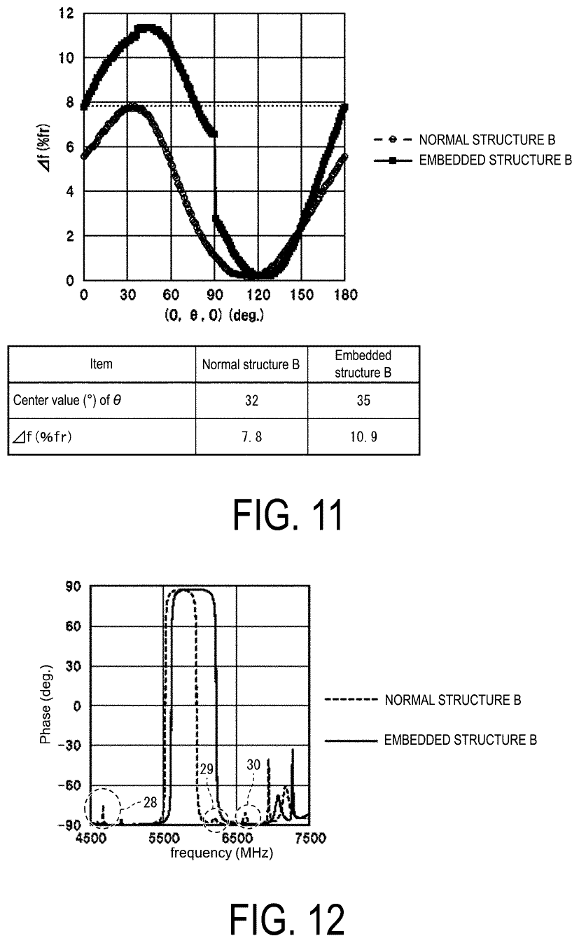

FIG. 11 is a graph showing the relationship of Δf shown on the vertical axis and expressed in units of % fr with respect to θ shown on the horizontal axis and expressed in units of deg, and a table summarizing a center value of θ and a maximum value of Δf in the embedded structure B and the normal structure B. The graph of FIG. 11 shows the relationship when φ=0° and ψ=0°.

According to the graph of FIG. 11, when θ is from 1° to 78° in the embedded structure B, Δf of the embedded structure B generally exceeds 7.8% fr, which is the maximum value of Δf of the normal structure B. It can be seen that a bandwidth of the embedded structure B is wider than that of the normal structure B. In the embedded structure B, it can be seen that θ may be in the range of 1 to 78°.

FIG. 12 is a graph showing the relationship of phase shown on the vertical axis and expressed in units of deg with respect to frequency shown on the horizontal axis and expressed in units of MHz in the embedded structure B and the normal structure B. FIG. 12 illustrates the relationship when θ=35°.

In the graph of FIG. 12, when the characteristics of the embedded structure B are compared with the characteristics of the normal structure B, spurious components 28 to 30 do not exist in the characteristics of the embedded structure B and exist only in the characteristics of the normal structure B. It can be seen that the spurious components are reduced in the embedded structure B as compared with the normal structure B.

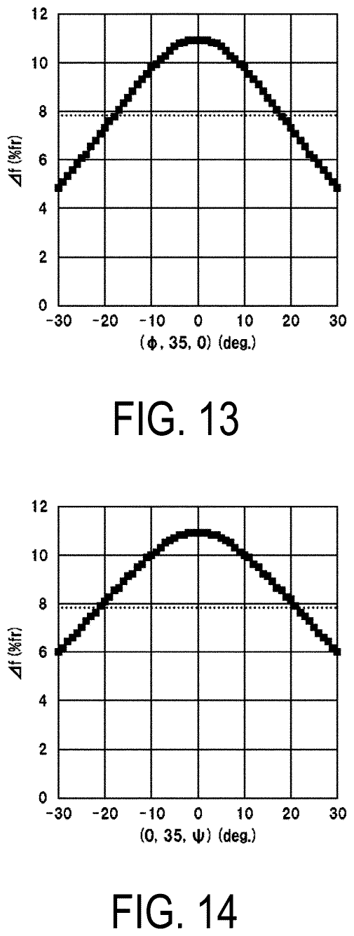

FIG. 13 is a graph showing the relationship of Δf shown on the vertical axis and expressed in units of % fr with respect to φ shown on the horizontal axis and expressed in units of deg in the embedded structure B. The graph of FIG. 13 shows the relationship when θ=35° and φ=0°.

According to FIG. 13, when φ=−17° or more and φ=17° or less, Δf of the embedded structure B exceeds 7.8% fr, which is the maximum value of Δf of the normal structure B. In the embedded structure B, it can be seen that φ may be in the range of −17 to 17°. According to FIG. 13, the center value of φ in the embedded structure B is 0°.

FIG. 14 is a graph showing the relationship of Δf shown on the vertical axis and expressed in units of % fr with respect to ψ shown on the horizontal axis and expressed in units of deg in the embedded structure B. The graph of FIG. 14 shows the relationship when φ=0° and θ=35°.

According to FIG. 14, when ψ=−21° or more and ψ=21° or less, Δf of the embedded structure B exceeds 7.8% fr, which is the maximum value of Δf of the normal structure B. In the embedded structure B, it can be seen that ψ may be in the range of −21 to 21°. According to FIG. 14, the center value of ψ in the embedded structure B is 0°.

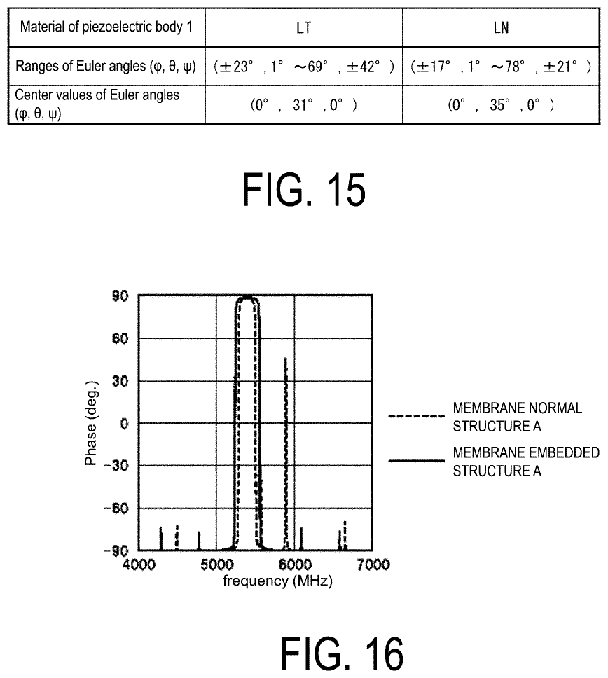

FIG. 15 is a table summarizing ranges and center values of φ, θ, and ψ derived for each material of the piezoelectric body 1. According to FIG. 15, the following can be said.

In the embedded structure A, the piezoelectric body 1 is made of lithium tantalate. In the embedded structure A, when the Euler angles of the piezoelectric body 1 are (φ, θ, ψ), φ may be in the range of −23 to 23°, θ may be in the range of 1 to 69°, and ψ may be in the range of −42 to 42°.

In the embedded structure B, the piezoelectric body 1 is made of lithium niobate. In the embedded structure B, when the Euler angles of the piezoelectric body 1 are (φ, θ, ψ), φ may be in the range of −17 to 17°, θ may be in the range of 1 to 78°, and ψ may be in the range of −21 to 21°.

In each of the elastic wave devices 101 and 101′, a membrane structure may be provided instead of the multilayer film 4. The membrane structure is a structure in which a concave portion is formed in the support substrate 5 on the piezoelectric body 1 side and the piezoelectric body 1 is disposed covering the concave portion.

A structure obtained by applying the membrane structure to the embedded structure A is referred to as a “membrane embedded structure A”, and a structure obtained by applying the membrane structure to the normal structure A is referred to as a “membrane normal structure A”.

FIG. 16 is a graph showing the relationship of phase shown on the vertical axis and expressed in units of deg with respect to frequency shown on the horizontal axis and expressed in units of MHz in the membrane embedded structure A and the membrane normal structure A. The graph of FIG. 16 shows the relationship when φ=0°, θ=31°, and ψ=0°. According to FIG. 16, it can be seen that the membrane embedded structure A also has the effect of reducing spurious components, similar to the embedded structure A.

A structure obtained by applying the membrane structure to the embedded structure B is referred to as a “membrane embedded structure B”, and a structure obtained by applying the membrane structure to the normal structure B is referred to as a “membrane normal structure B”.

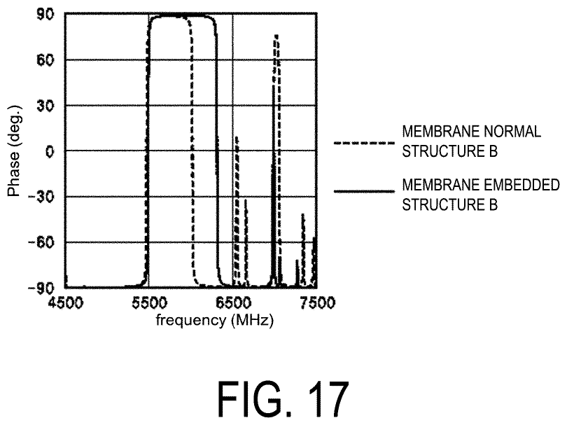

FIG. 17 is a graph showing the relationship of phase shown on the vertical axis and expressed in units of deg with respect to frequency shown on the horizontal axis and expressed in units of MHz in the membrane embedded structure B and the membrane normal structure B. The graph of FIG. 17 shows the relationship when φ=0°, θ=32°, and ψ=0°. According to FIG. 17, it can be seen that the membrane embedded structure B also has the effect of reducing spurious components, similar to the embedded structure B.

The embedded structure A, the embedded structure B, the membrane embedded structure A, and the membrane embedded structure B are collectively referred to as “embedded structures”. Vibration excited by the embedded structure is in the A₁ mode, which is an antisymmetric mode.

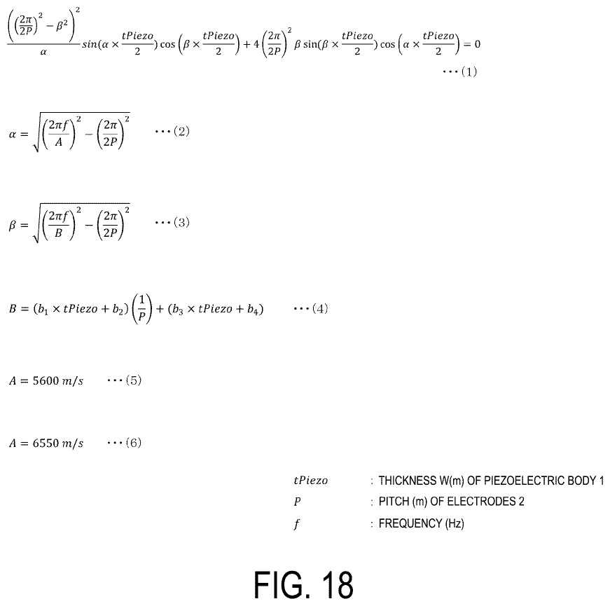

FIG. 18 illustrates Equations (1) to (6). The numerical value of each of b₁, b₂, b₃, and b₄ is a variable. tPiezo denotes a thickness W (m) of the piezoelectric body 1, and P denotes a pitch (m) of the electrodes 2 and is determined by the structure of the elastic wave device. Equation (5) is for LT, and Equation (6) is for LN.

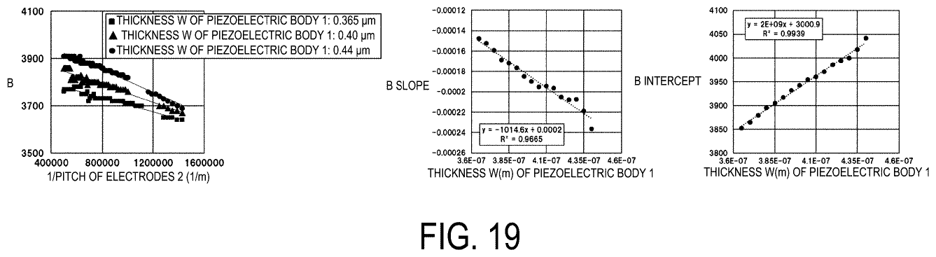

FIG. 19 is three types of graphs when the piezoelectric body 1 is made of LT. The three types of graphs are respectively as follows.

Left: Dependence of B on the reciprocal of the pitch of the electrodes 2 in units of m

Middle: Dependence of the slope of B on the thickness W of the piezoelectric body 1 in units of m Right: Dependence of the intercept of B on the thickness W of the piezoelectric body 1 in units of m

According to FIG. 19, it can be seen that Equation (4) shows that B has linear dependence on the reciprocal of the pitch of the electrodes 2 and that each of the slope and the intercept of B has linear dependence on the thickness W of the piezoelectric body 1.

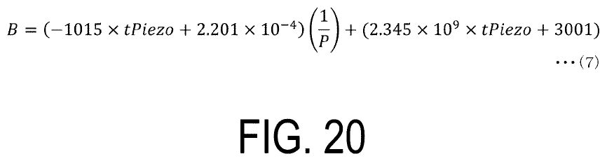

FIG. 20 illustrates Equation (7). Equation (7) is fitted to coincide with a resonance frequency obtained from FEM on the assumption that the piezoelectric body 1 is made of LT.

When the piezoelectric body 1 is made of LT, A=5600 m/s (meters per second), b₁=−1015 m/s, b₂=2.201×10⁻⁴ m²/s, b₃=2.345×10⁹/s, and b₄=3001 m/s.

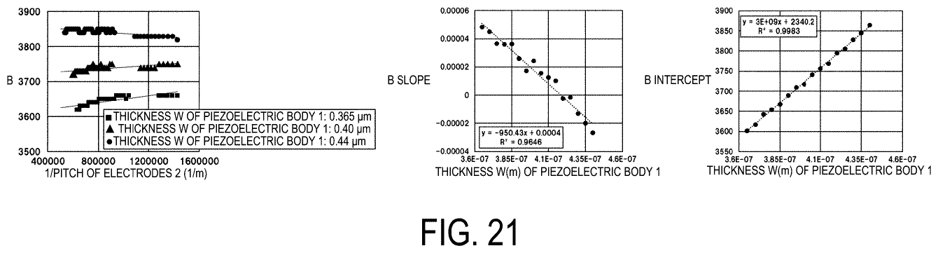

FIG. 21 is three types of graphs when the piezoelectric body 1 is made of LN. The three types of graphs are respectively as follows.

Left: Dependence of B on the reciprocal of the pitch of the electrodes 2 in units of m

Middle: Dependence of the slope of B on the thickness W of the piezoelectric body 1 in units of m

Right: Dependence of the intercept of B on the thickness W of the piezoelectric body 1 in units of m

According to FIG. 21, it can be seen that Equation (4) shows that B has linear dependence on the reciprocal of the pitch of the electrodes 2 and that each of the slope and the intercept of B has linear dependence on the thickness W of the piezoelectric body 1.

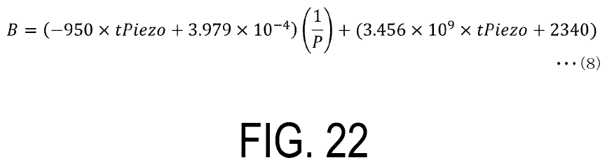

FIG. 22 illustrates Equation (8). Equation (8) is fitted to coincide with a resonance frequency obtained from FEM on the assumption that the piezoelectric body 1 is made of LN. When the piezoelectric body 1 is made of LN, A=6550 m/s, b₁=−950 m/s, b₂=3.979×10⁻⁴ m²/s, b₃=3.456×10⁹/s, and b₄=2340 m/s.

In the elastic wave device 101, frequencies f obtained by Equations (1) to (8) may be 3 GHz or more.

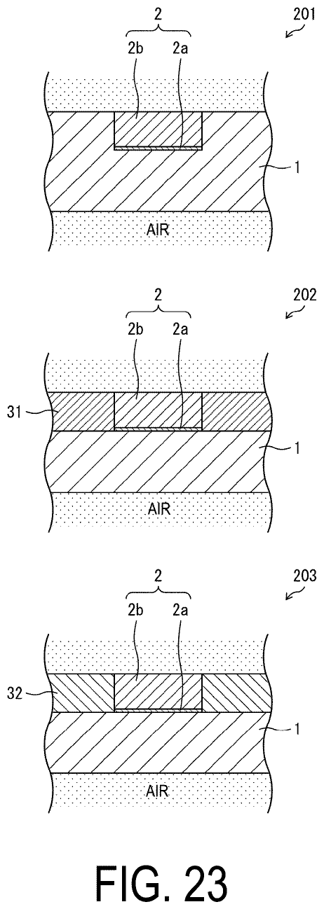

FIG. 23 illustrates three types of structures of the elastic wave device. The three types of structures are structures 201 to 203, respectively.

The structure 201 includes a piezoelectric body 1 and an electrode 2, and at least a part of the electrode 2 is embedded in the piezoelectric body 1.

The structure 202 includes a piezoelectric body 1, an electrode 2, and an LT film 31 having no piezoelectric property. In the structure 202, the electrode 2 is not embedded in the piezoelectric body 1. In the structure 202, the electrode 2 and the LT film 31 are formed on an upper surface of the piezoelectric body 1 having a plate shape. In the structure 202, the electrode 2 is embedded in the LT film 31.

The structure 203 includes a piezoelectric body 1, an electrode 2, and a film 32. The film 32 is made of SiO₂. In the structure 203, the electrode 2 is not embedded in the piezoelectric body 1. In the structure 203, the electrode 2 and the film 32 are formed on the upper surface of the piezoelectric body 1 having a plate shape. In the structure 203, the electrode 2 is embedded in the film 32.

Each of the structures 201 to 203 uses a Lamb wave such as the A₁ mode, which is an antisymmetric mode. In each of the structures 201 to 203, the following conditions are determined. The material of the piezoelectric body 1 is LT. The thickness of the piezoelectric body 1 is 400 nm. The Euler angles of the piezoelectric body 1 are φ=0° and ψ=0°. The material of the first layer 2a is titanium. The thickness of the first layer 2a is 6 nm. The material of the second layer 2b is aluminum. The thickness of the second layer 2b is 124 nm.

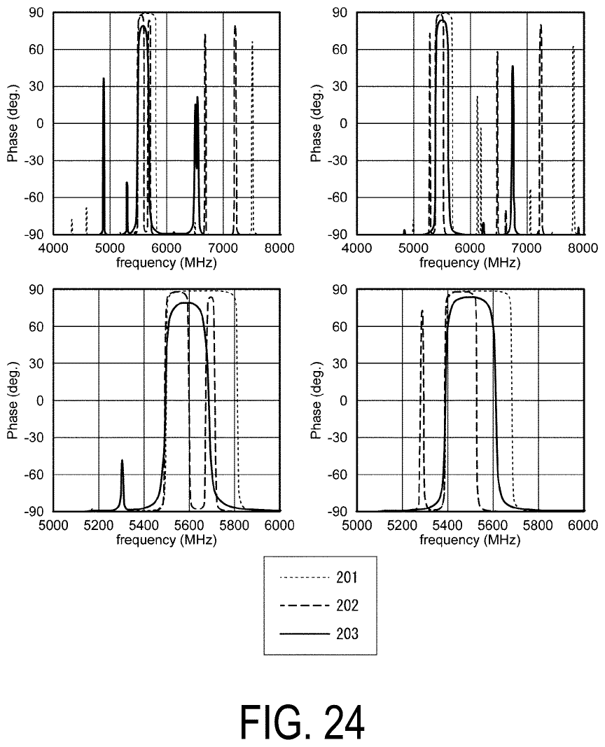

FIG. 24 is four types of graphs illustrating the relationship of phase shown on the vertical axis and expressed in units of deg with respect to frequency shown on the horizontal axis and expressed in units of MHz in the structures 201 to 203. In each graph of FIG. 24, a dotted line indicates the characteristics of the structure 201, a broken line indicates the characteristics of the structure 202, and a solid line indicates the characteristics of the structure 203.

According to FIG. 24, Δf can be made larger in the structure 201 than in the structures 202 and 203. It can be seen that the configuration in which at least a part of the electrode 2 is embedded in the piezoelectric body 1 is effective. In the structure 203, loss of a so-called Z-ratio is also a factor of increase in loss.

### Second Embodiment

The upper end of the electrode 2 may include a highest portion that is the highest position in the electrode 2 when the elastic wave device is in an upright state, and a semi-high portion lower than the highest portion. This means that the height of the upper end of the electrode 2 may be non-uniform. Examples of the cross-sectional shape of the upper end of the electrode 2 include a mountain shape (convex shape), a recessed shape (concave shape), an M shape being a combination of a convex shape and a concave shape, and a W shape being a combination of a convex shape and a concave shape.

The upper end of the electrode 2 may be rounded such that the upper end of the electrode 2 and the upper end of the piezoelectric body 1 can be connected by a smooth line. Examples of the smooth line include a single straight line, a single curved line, a line connecting a straight line and a curved line, and a line connecting a curved line and a curved line.

The first layer 2a may be in contact with the side surface of the second layer 2b. A typical example is a configuration in which the first layer 2a covers at least a part of the side surface of the second layer 2b.

The elastic wave device 101 may include a base layer of the electrode 2 including a dielectric.

### Third Embodiment

A communication apparatus including the elastic wave device 101 is also included in the scope of the present disclosure. The communication apparatus may perform wireless communication using radio waves. In the communication apparatus, the elastic wave device 101 may be used as a filter of a duplexer, for example.

### Fourth Embodiment

An advantageous configuration of the elastic wave device 101 was searched for by simulation using a simulation structure that imitates the elastic wave device 101. Items of the simulation are the positional relationship between the upper surface of the electrode 2 and the upper surface of the piezoelectric body 1, the thickness of the electrode 2, the Duty, and the derived structure. The advantageous configuration of the elastic wave device 101 can be essentially regarded as identical to the advantageous configuration of the simulation structure.

### Positional Relationship Between Upper Surface of Electrode 2 and Upper Surface of Piezoelectric Body 1

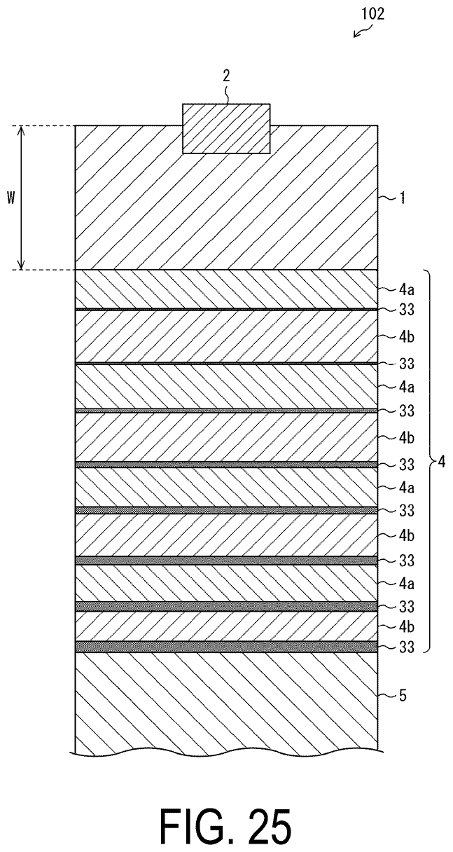

FIG. 25 is a cross-sectional view of a first simulation structure 102. The first simulation structure 102 is different from the elastic wave device 101 in that the protective film 3 is not provided and the multilayer film 4 includes mixed layers 33. The mixed layer 33 is formed under the low acoustic impedance layer 4a and under the high acoustic impedance layer 4b, and is a layer including both the material of the low acoustic impedance layer 4a and the material of the high acoustic impedance layer 4b. The presence or absence of the mixed layer 33 does not significantly change the essential characteristics of the elastic wave device 101.

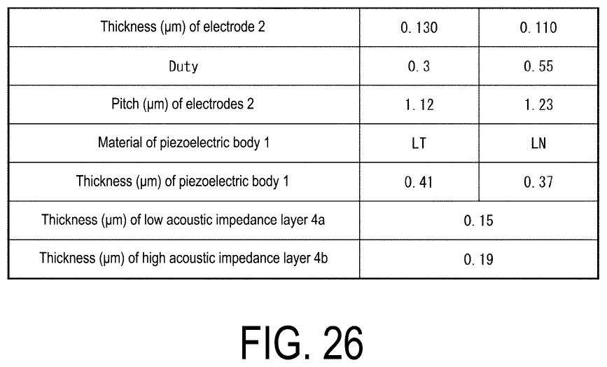

FIG. 26 is a table showing various configurations of the first simulation structure 102 used for the simulation of the positional relationship between the upper surface of the electrode 2 and the upper surface of the piezoelectric body 1. FIG. 26 shows a case where the material of the piezoelectric body 1 is LT and a case where the material of the piezoelectric body 1 is LN. In the first simulation structure 102, the electrode 2 is made of the same material as the second layer 2b. The numerical values illustrated in FIG. 26 are basic values and can be changed as appropriate when the simulation is performed.

The configuration in which at least a part of the electrode 2 is embedded in the piezoelectric body 1 can be classified into a convex structure in which the upper surface of the electrode 2 protrudes with respect to the upper surface of the piezoelectric body 1 and a concave structure in which the upper surface of the electrode 2 is recessed with respect to the piezoelectric body 1.

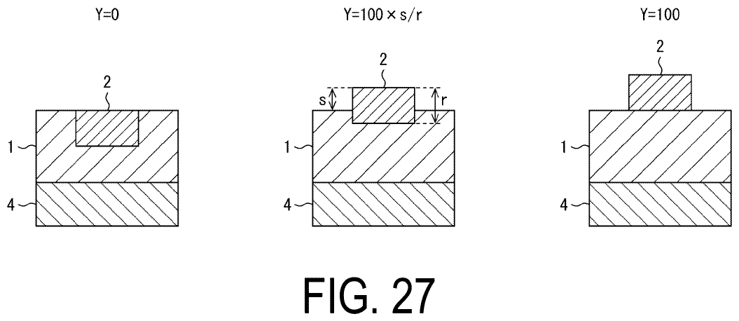

FIG. 27 is a diagram for explaining the definition of a variable Y in the convex structure. The variable Y is represented by 100×s/r, where r is the thickness of the electrode 2 and s is the distance between the upper end of the electrode 2 and the upper end of the piezoelectric body 1 along the thickness direction of the piezoelectric body 1. Y is 0 when the upper surface of the electrode 2 is flush with the upper surface of the piezoelectric body 1. Y is 100 when the electrode 2 is not embedded in the piezoelectric body 1 as in the elastic wave device 101′.

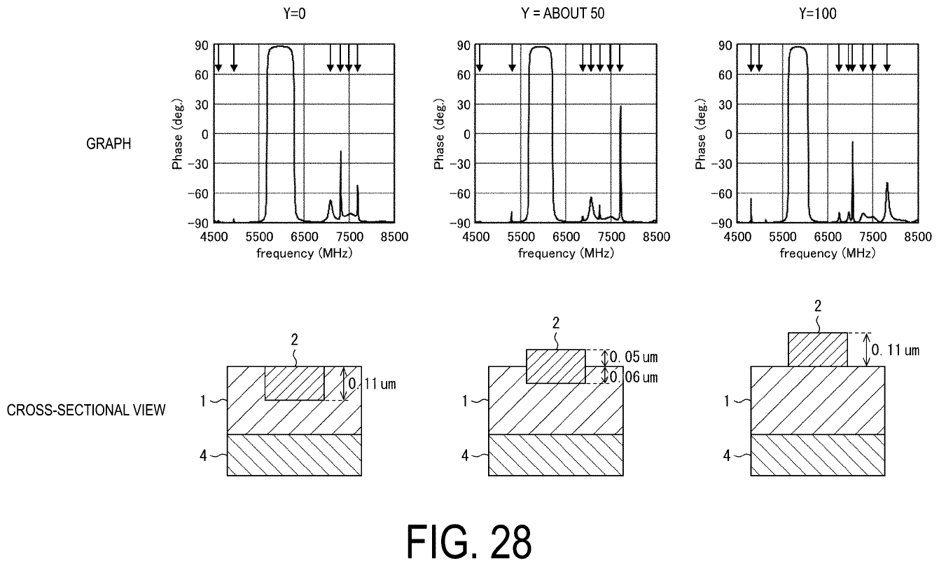

In FIG. 28, a graph showing the relationship of a phase with respect to a frequency in the convex structure in which the material of the piezoelectric body 1 is LN is shown together with corresponding cross-sectional views of the piezoelectric body 1 and the electrode 2. FIG. 28 shows graphs when Y=0, when Y=about 50 (5/0.11), and when Y=100. According to FIG. 28, it can be seen that the smaller Y is, the more the spurious component is reduced.

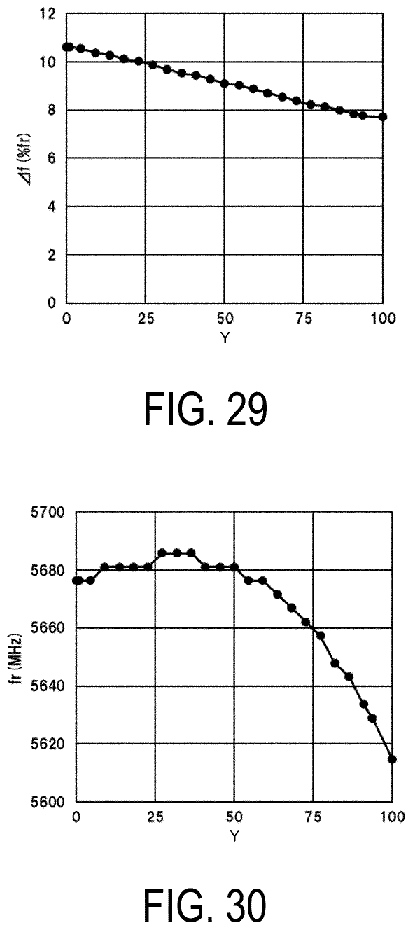

FIG. 29 is a graph showing the relationship of Δf shown on the vertical axis and expressed in units of % fr with respect to the value of Y shown on the horizontal axis and expressed in no units in the convex structure in which the material of the piezoelectric body 1 is LN. FIG. 30 is a graph showing the relationship of resonance frequency fr shown on the vertical axis in units of MHz with respect to the value of Y shown on the horizontal axis and expressed in no units in the convex structure in which the material of the piezoelectric body 1 is LN.

According to FIG. 29, it can be seen that Δf increases as Y decreases. According to FIG. 30, when Y exceeds about 50, fr tends to decrease and the sound velocity tends to decrease.

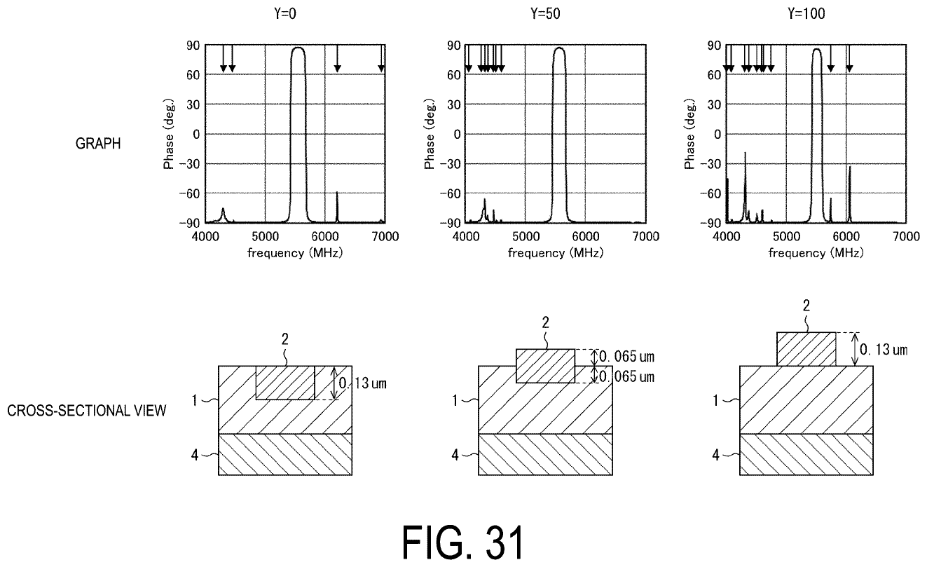

In FIG. 31, a graph showing the relationship of phase with respect to frequency in the convex structure in which the material of the piezoelectric body 1 is LT is shown together with corresponding cross-sectional views of the piezoelectric body 1 and the electrode 2. FIG. 31 illustrates graphs when Y=0, when Y=50, and when Y=100. According to FIG. 31, it can be seen that the smaller Y is, the more the spurious component is reduced.

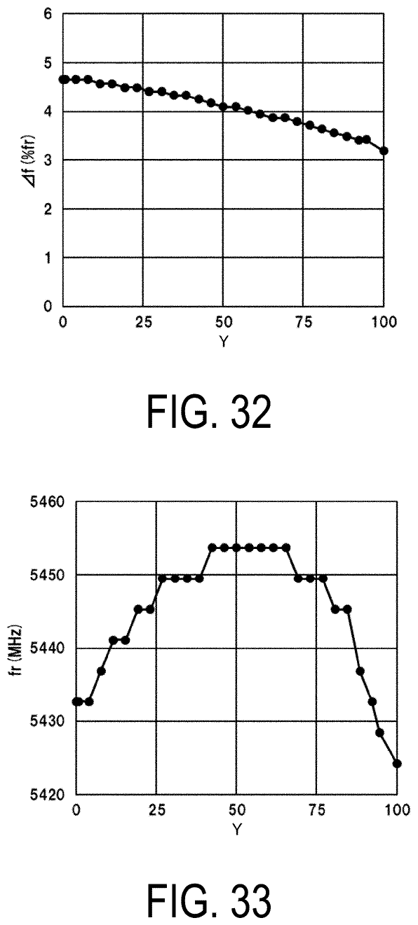

FIG. 32 is a graph showing the relationship of Δf shown on the vertical axis and expressed in units of % fr with respect to the value of Y shown on the horizontal axis and expressed in no units in the convex structure in which the material of the piezoelectric body 1 is LT. FIG. 33 is a graph showing the relationship of resonance frequency fr shown on the vertical axis in units of MHz with respect to the value of Y shown on the horizontal axis and expressed in no units in the convex structure in which the material of the piezoelectric body 1 is LT.

According to FIG. 32, it can be seen that Δf increases as Y decreases. According to FIG. 33, when Y is less than about 25 or exceeds 75, fr tends to decrease and the sound velocity tends to decrease.

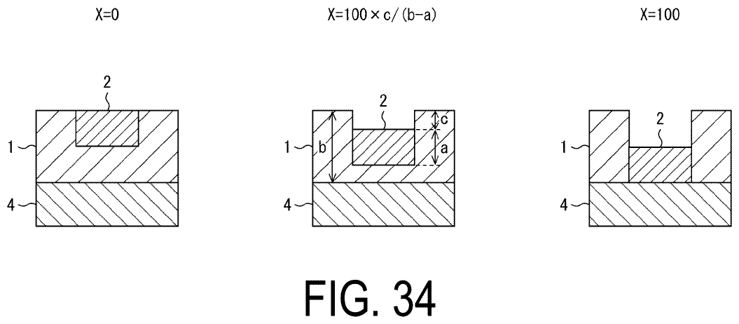

FIG. 34 is a diagram for explaining the definition of a variable X in the concave structure. The variable X is represented by 100×c/(b−a), where a is the thickness of the electrode 2, b is the thickness of the piezoelectric body 1, and c is the distance between the upper end of the electrode 2 and the upper end of the piezoelectric body 1 along the thickness direction of the piezoelectric body 1. X is 0 when the upper surface of the electrode 2 is flush with the upper surface of the piezoelectric body 1. X is 100 when the bottom surface of the electrode 2 is flush with the bottom surface of the piezoelectric body 1.

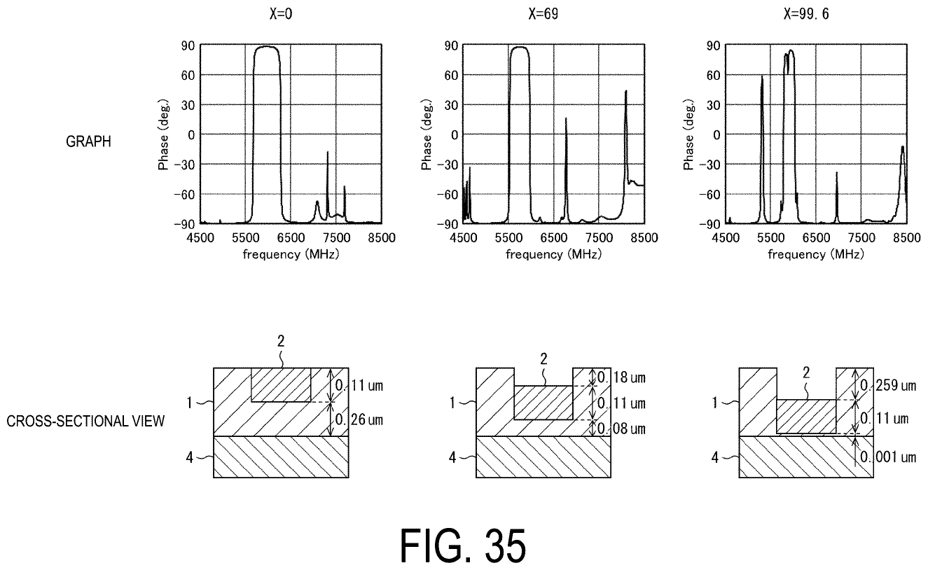

In FIG. 35, a graph showing the relationship of phase with respect to frequency in the concave structure in which the material of the piezoelectric body 1 is LN is shown together with corresponding cross-sectional views of the piezoelectric body 1 and the electrode 2. FIG. 35 shows graphs when X=0, when X=69, and when X=99.6. According to FIG. 35, it can be seen that the smaller X is, the more the spurious component is reduced.

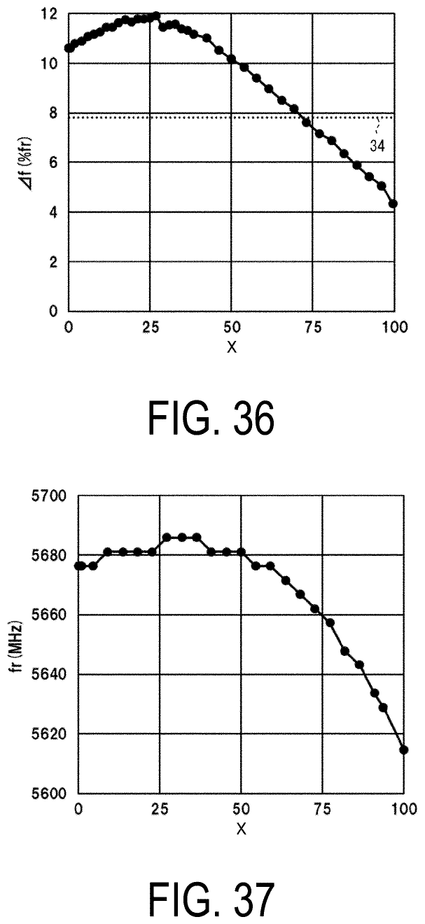

FIG. 36 is a graph showing the relationship of Δf shown on the vertical axis and expressed in units of % fr with respect to the value of X shown on the horizontal axis and expressed in no units in the concave structure in which the material of the piezoelectric body 1 is LN. FIG. 37 is a graph showing the relationship of resonance frequency fr shown on the vertical axis and expressed in units of MHz with respect to the value of X shown on the horizontal axis and expressed in no units in the concave structure in which the material of the piezoelectric body 1 is LN.

According to FIG. 36, when X exceeds about 25, Δf decreases as X increases. In FIG. 36, a dotted line 34 indicates Δf when Y=100 in the convex structure in which the material of the piezoelectric body 1 is LN. The condition of X in which Δf is above the dotted line 34 was confirmed to be X≤69. That is, when the piezoelectric body 1 is made of LN in the concave structure, 100×c/(b−a)≤69 may be satisfied. According to FIG. 37, when X exceeds about 50, fr tends to decrease and the sound velocity tends to decrease.

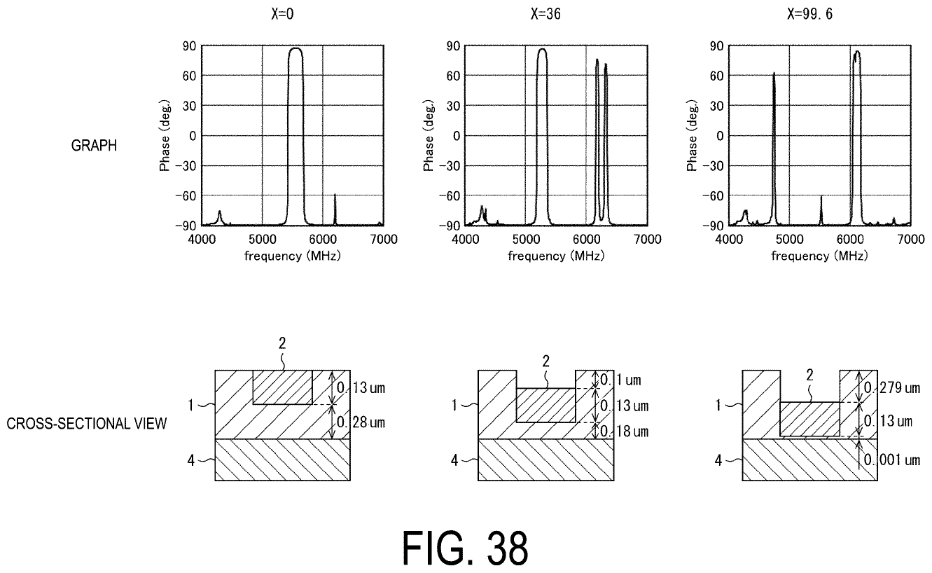

In FIG. 38, a graph showing the relationship of phase with respect to frequency in the concave structure in which the material of the piezoelectric body 1 is LT is shown together with corresponding cross-sectional views of the piezoelectric body 1 and the electrode 2. FIG. 38 shows graphs when X=0, when X=36, and when X=99.6. According to FIG. 38, it can be seen that the smaller X is, the more the spurious component is reduced.

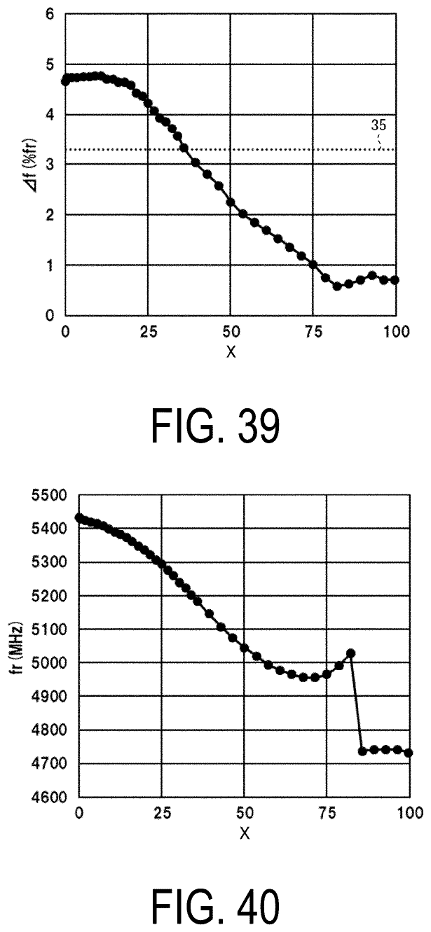

FIG. 39 is a graph showing the relationship of Δf shown on the vertical axis and expressed in units of % fr with respect to the value of X shown on the horizontal axis and expressed in no units in the concave structure in which the material of the piezoelectric body 1 is LT. FIG. 40 is a graph showing the relationship of resonance frequency fr shown on the vertical axis and expressed in units of MHz with respect to the value of X shown on the horizontal axis and expressed in no units in the concave structure in which the material of the piezoelectric body 1 is LT.

According to FIG. 39, when X exceeds about 20, Δf decreases as X increases. In FIG. 39, a dotted line 35 indicates Δf when Y=100 in the convex structure in which the material of the piezoelectric body 1 is LT. The condition of X in which Δf is above the dotted line 35 was confirmed to be X≤36. That is, when the piezoelectric body 1 is made of LT in the concave structure, 100×c/(b−a)≤36 may be satisfied. According to FIG. 40, roughly speaking, as X increases, fr tends to decrease and the sound velocity tends to decrease.

### Thickness of Electrode 2

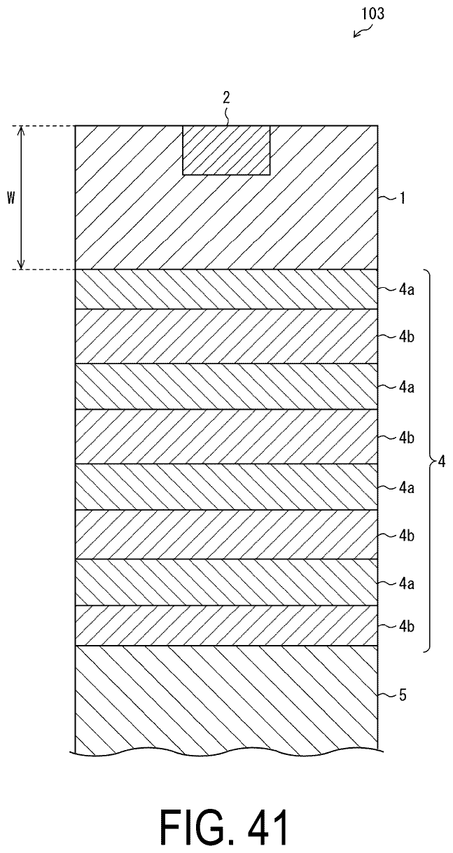

FIG. 41 is a cross-sectional view of a second simulation structure 103. The second simulation structure 103 is different from the elastic wave device 101 in that the protective film 3 is not provided.

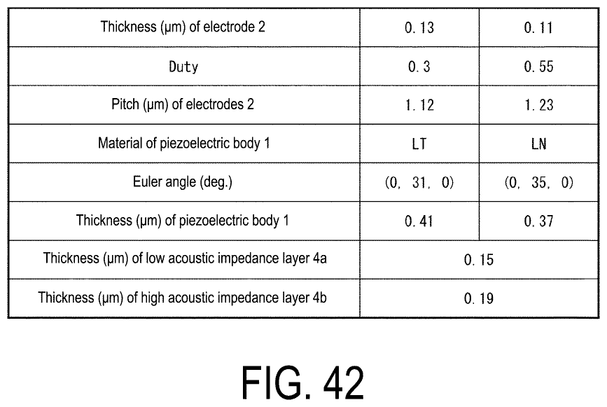

FIG. 42 is a table showing various configurations of the second simulation structure 103 used for simulation of the thickness of the electrode 2. FIG. 42 illustrates a case where the material of the piezoelectric body 1 is LT and a case where the material of the piezoelectric body 1 is LN. In the second simulation structure 103, the electrode 2 is made of the same material as the second layer 2b. The numerical values illustrated in FIG. 42 are basic values, and can be changed as appropriate when the simulation is performed.

The thickness of the electrode 2 may be expressed by either a dimension in units of nm or a percentage of the thickness of the piezoelectric body 1 in units of % tPiezo.

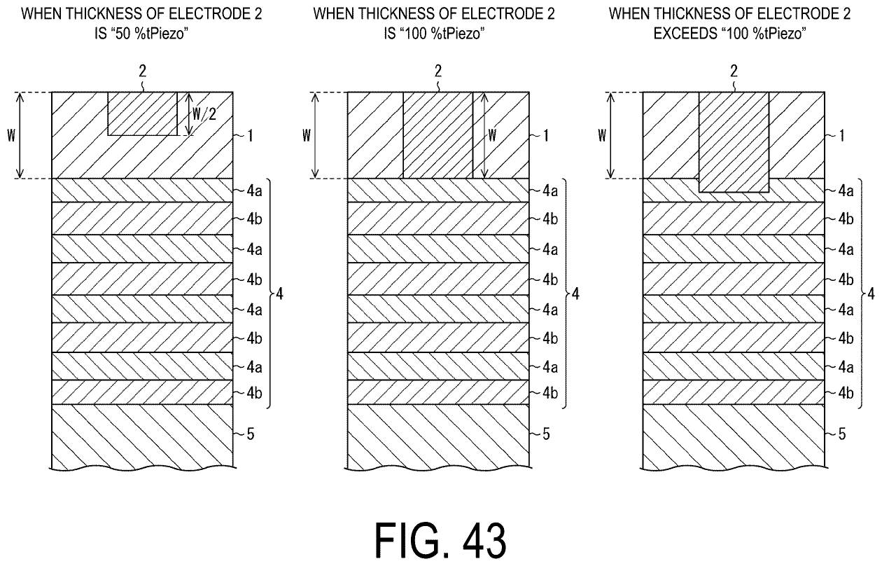

FIG. 43 is cross-sectional views of the piezoelectric body 1 and the electrode 2 for explaining the expression of the thickness of the electrode 2 by the percentage of the thickness of the piezoelectric body 1. When the thickness of the electrode 2 is 100% tPiezo or less, the upper surface of the electrode 2 and the upper surface of the piezoelectric body 1 are flush with each other. When the thickness of the electrode 2 is 100% tPiezo, the bottom surface of the electrode 2 and the bottom surface of the piezoelectric body 1 are flush with each other. When the thickness of the electrode 2 exceeds 100% tPiezo, the bottom surface of the electrode 2 protrudes from the bottom surface of the piezoelectric body 1. The bottom surface of the electrode 2 is located, for example, inside the low acoustic impedance layer 4a located closest to the piezoelectric body 1.

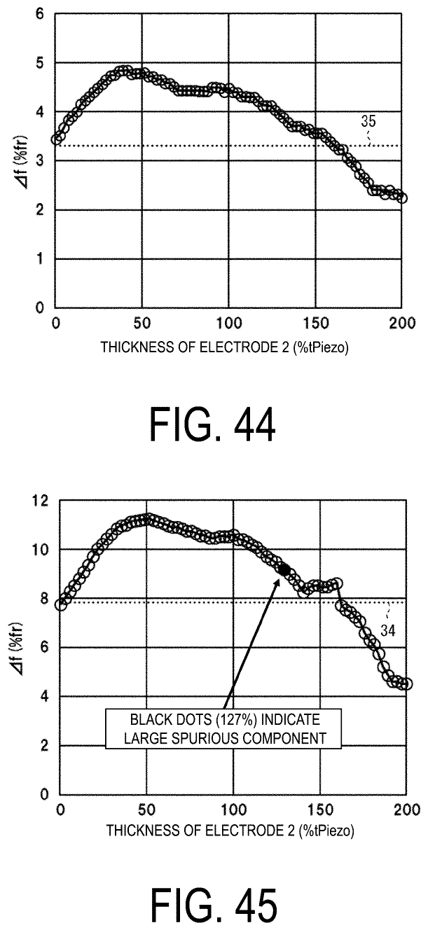

FIG. 44 is a graph showing the relationship of Δf shown on the vertical axis and expressed in units of % fr with respect to the thickness of the electrode 2 shown on the horizontal axis and expressed in units of % tPiezo when the material of the piezoelectric body 1 is LT. FIG. 45 is a graph showing the relationship of Δf shown on the vertical axis and expressed in units of % fr with respect to the thickness of the electrode 2 shown on the horizontal axis and expressed in units of % tPiezo when the material of the piezoelectric body 1 is LN.

When the material of the piezoelectric body 1 is LT, the condition of the thickness of the electrode 2 in which Δf is above the dotted line 35 was confirmed to be 161% tPiezo or less. When the material of the piezoelectric body 1 is LN, the condition of the thickness of the electrode 2 in which Δf is above the dotted line 34 was confirmed to be about 160% tPiezo or less. However, in a case where the material of the piezoelectric body 1 is LN, when the thickness of the electrode 2 is 127% tPiezo or more, a spurious component increases.

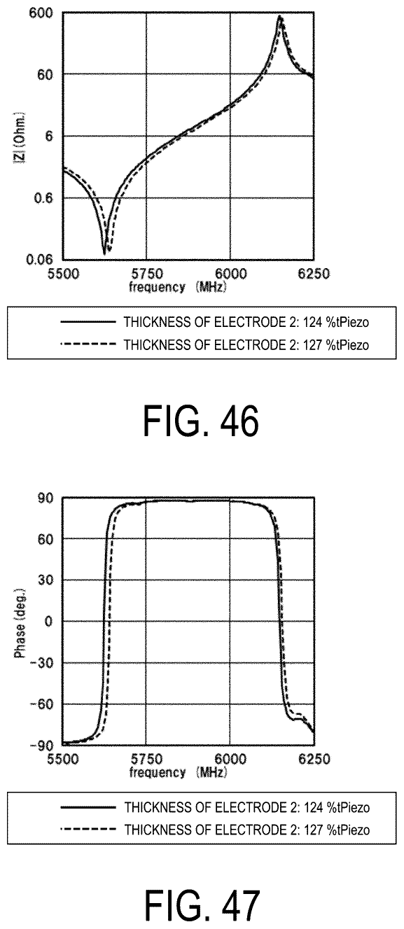

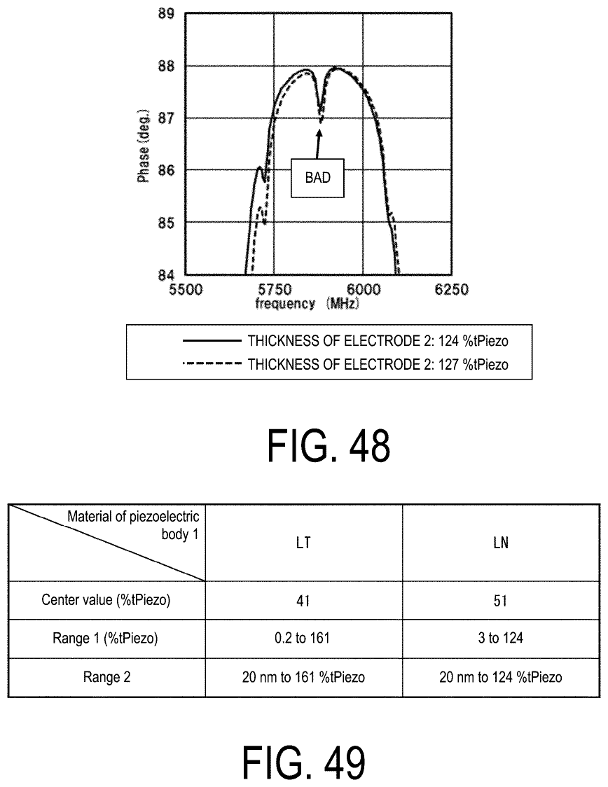

FIG. 46 is a graph showing the relationship of impedance shown on the vertical axis and expressed in units of ohm with respect to frequency shown on the horizontal axis and expressed in units of MHz when the material of the piezoelectric body 1 is LN. FIG. 47 is a graph showing the relationship of phase shown on the vertical axis and expressed in units of deg with respect to frequency shown on the horizontal axis and expressed in units of MHz when the material of the piezoelectric body 1 is LN. FIG. 48 is another graph showing the relationship of phase shown on the vertical axis and expressed in units of deg with respect to frequency shown on the horizontal axis and expressed in units of MHz when the material of the piezoelectric body 1 is LN.

Each of FIGS. 46 to 48 illustrates characteristics when the thickness of the electrode 2 is 124% tPiezo and characteristics when the thickness of the electrode 2 is 127% tPiezo. Notice the depth of the valley in the graph located near 5850 MHz in FIG. 48. A case where the depth is less than the 1 deg is determined to be good, and a case where the depth is 1 deg or more is determined to be bad because the reduction of spurious components is likely to be adversely affected. The case where the thickness of the electrode 2 is 124% tPiezo is good, and the case where the thickness of the electrode 2 is 127% tPiezo is bad.

In addition, the thickness of the electrode 2 is generally 20 nm or more.

FIG. 49 is a table summarizing advantageous configurations of the thickness of the electrode 2. The thickness of the electrode 2 may be in a range 1 in FIG. 49 or in a range 2 in FIG. 49. When the piezoelectric body 1 is made of LT, the thickness of the electrode 2 may be 0.2% or more of the thickness of the piezoelectric body 1 and may be 161% or less of the thickness of the piezoelectric body 1, or may be 20 nm or more and may be 161% or less of the thickness of the piezoelectric body 1. When the piezoelectric body 1 is made of LN, the thickness of the electrode 2 may be 3% or more of the thickness of the piezoelectric body 1 and may be 124% or less of the thickness of the piezoelectric body 1, or may be 20 nm or more and may be 124% or less of the thickness of the piezoelectric body 1.

### Duty

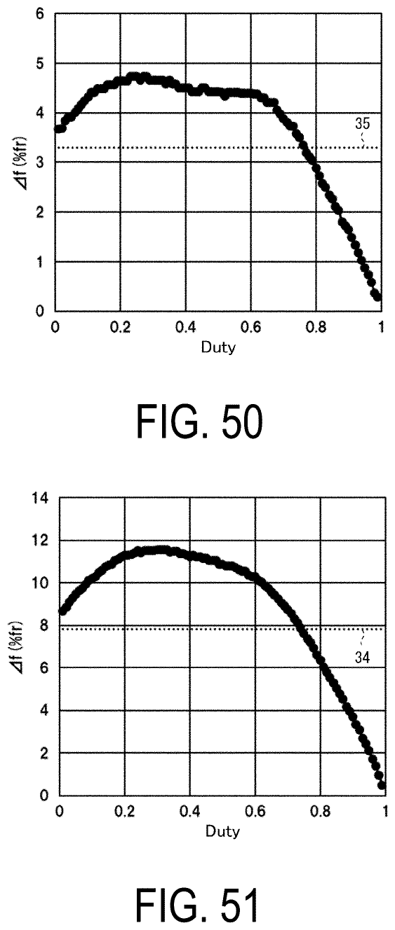

FIG. 50 is a graph showing the relationship of Δf shown on the vertical axis and expressed in units of % fr with respect to Duty shown on the horizontal axis and expressed in no units when the material of the piezoelectric body 1 is LT. FIG. 51 is a graph showing the relationship of Δf shown on the vertical axis and expressed in units of % fr with respect to Duty shown on the horizontal axis and expressed in no units when the material of the piezoelectric body 1 is LN.

When the material of the piezoelectric body 1 is LT, the condition of Duty in which Δf is above the dotted line 35 was confirmed to be 0.76 or less. When the material of the piezoelectric body 1 is LN, the condition of Duty in which Δf is above the dotted line 34 was confirmed to be 0.74 or less. In addition, the width of the electrode finger 2f of the electrode 2 is generally 0.3 μm or more.

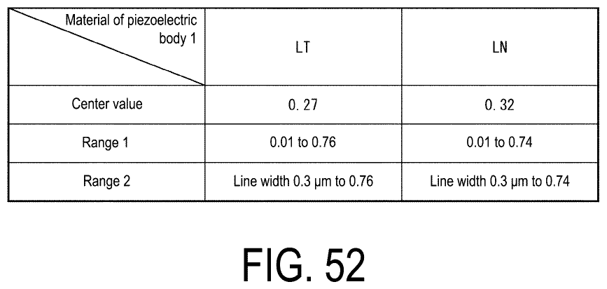

FIG. 52 is a table summarizing advantageous configurations of Duty. Duty may be in a range 1 in FIG. 52. Duty and the width of the electrode finger 2f of the electrode 2 may be in a range 2 in FIG. 52. When the piezoelectric body 1 is made of LT, Duty may be from 0.01 to 0.76. When the piezoelectric body 1 is made of LT, the width of the electrode finger 2f of the electrode 2 may be 0.3 μm or more, and Duty may be 0.76 or less. When the piezoelectric body 1 is made of LN, Duty may be from 0.01 to 0.74. When the piezoelectric body 1 is made of LN, the width of the electrode finger 2f of the electrode 2 may be 0.3 μm or more, and Duty may be 0.74 or less.

### Derived Structure

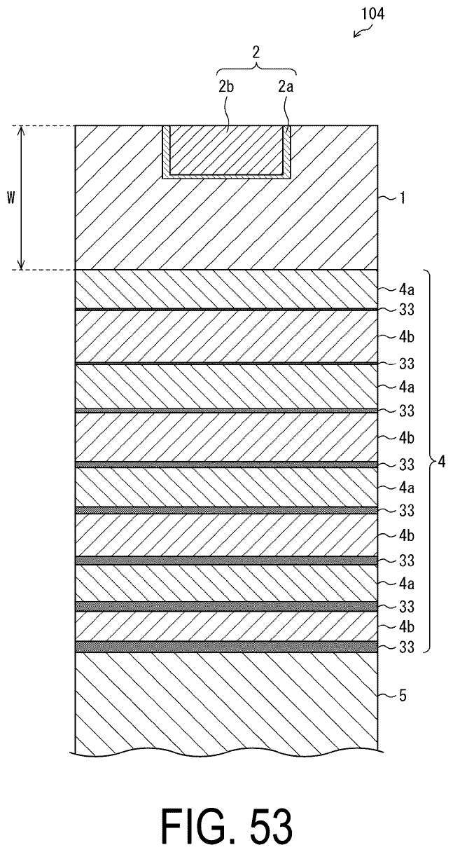

FIG. 53 is a cross-sectional view of a third simulation structure 104. The third simulation structure 104 is different from the first simulation structure 102 in that the electrode 2 includes a first layer 2a and a second layer 2b. In the third simulation structure 104, the second layer 2b is disposed on the first layer 2a, and the first layer 2a is in contact with the side surface of the second layer 2b.

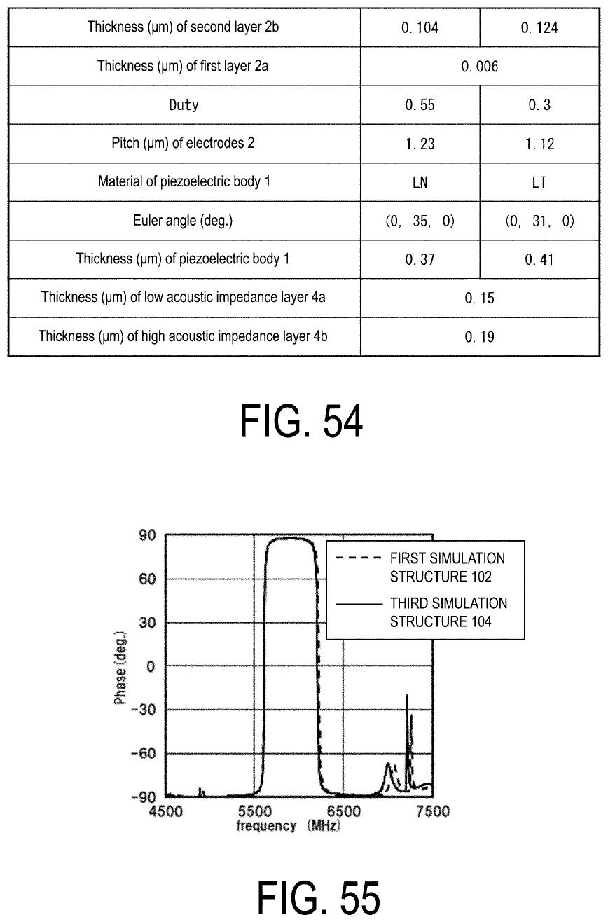

FIG. 54 is a table showing various configurations of the third simulation structure 104 used for simulation of the derivative structure. FIG. 54 shows a case where the material of the piezoelectric body 1 is LT and a case where the material of the piezoelectric body 1 is LN. The numerical values illustrated in FIG. 54 are basic values and can be changed as appropriate when the simulation is performed.

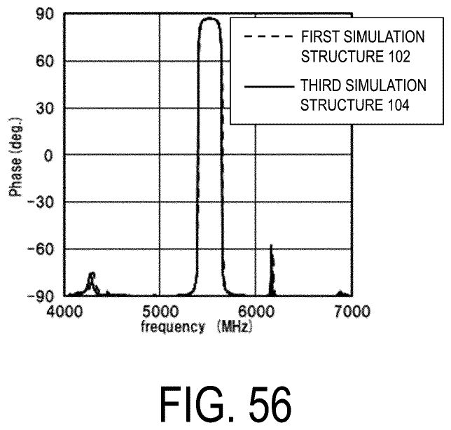

FIG. 55 is a graph showing the relationship of phase shown on the vertical axis and expressed in units of deg with respect to frequency shown on the horizontal axis and expressed in units of MHz when the material of the piezoelectric body 1 is LN. FIG. 56 is a graph showing the relationship of phase shown on the vertical axis and expressed in units of deg with respect to frequency shown on the horizontal axis and expressed in units of MHz when the material of the piezoelectric body 1 is LT.

Each of FIGS. 55 and 56 shows the characteristics of the first simulation structure 102 and the characteristics of the third simulation structure 104. No significant difference exists between the characteristics of the first simulation structure 102 and the characteristics of the third simulation structure 104.

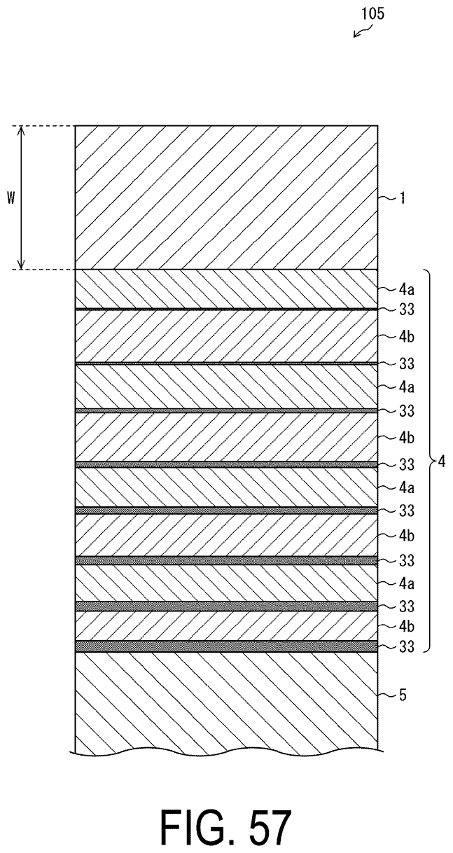

FIG. 57 is a cross-sectional view of a fourth simulation structure 105. The fourth simulation structure 105 is different from the first simulation structure 102 in that back surface embedding or full surface embedding to be described below is employed. Since the arrangement of the electrode 2 is different between back surface embedding and full surface embedding, the electrode 2 is not illustrated in FIG. 57.

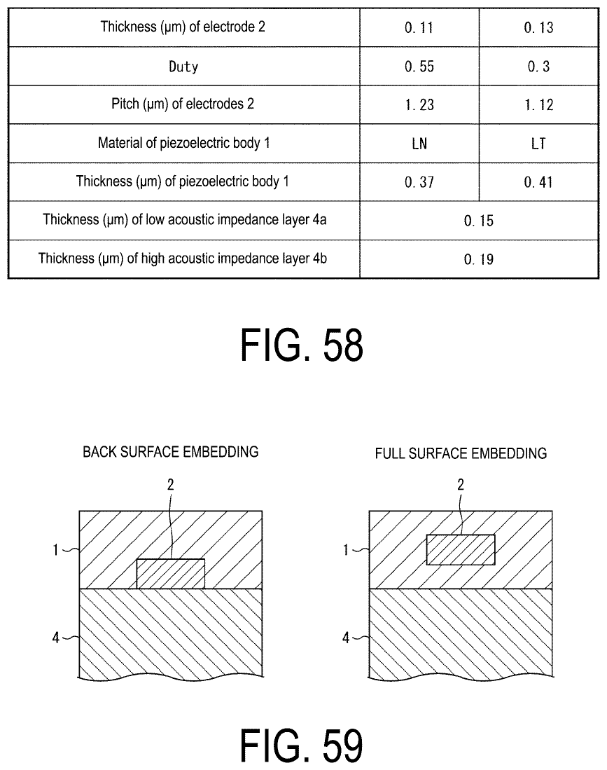

FIG. 58 is a table showing various configurations of the fourth simulation structure 105 used for simulation of the derivative structure. FIG. 58 shows a case where the material of the piezoelectric body 1 is LT and a case where the material of the piezoelectric body 1 is LN. In the fourth simulation structure 105, the electrode 2 is made of the same material as the second layer 2b. The numerical values shown in FIG. 58 are basic values and can be changed as appropriate when the simulation is performed.

FIG. 59 is cross-sectional views of the back surface embedding and the full surface embedding. The back surface embedding is a structure in which at least a part of the electrode 2 is embedded in the piezoelectric body 1 such that the bottom surface of surfaces of the electrode 2 is not in contact with the piezoelectric body 1 and the entire surface other than the bottom surface is in contact with the piezoelectric body 1. The full surface embedding is a structure in which at least a part of the electrode 2 is embedded in the piezoelectric body 1 such that the entire surface of the electrode 2 is in contact with the piezoelectric body 1.

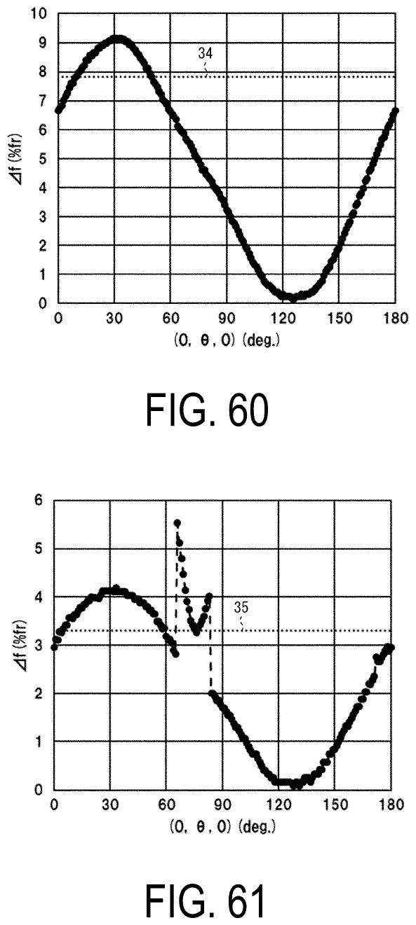

FIG. 60 is a graph showing the relationship of Δf shown on the vertical axis and expressed in units of % fr with respect to θ shown on the horizontal axis and expressed in units of deg in the back surface embedding in which the material of the piezoelectric body 1 is LN. FIG. 61 is a graph showing the relationship of Δf shown on the vertical axis and expressed in units of % fr with respect to θ shown on the horizontal axis and expressed in units of deg in the back surface embedding in which the material of the piezoelectric body 1 is LT. It is assumed that φ=0° and ψ=0° in the back surface embedding and the full surface embedding.

In the back surface embedding in which the material of the piezoelectric body 1 is LN, the condition of θ in which Δf is above the dotted line 34 was confirmed to be from 10° to 50°. In the back surface embedding in which the material of the piezoelectric body 1 is LT, the condition of θ in which Δf is stably above the dotted line 35 was confirmed to be from 5° to 59°.

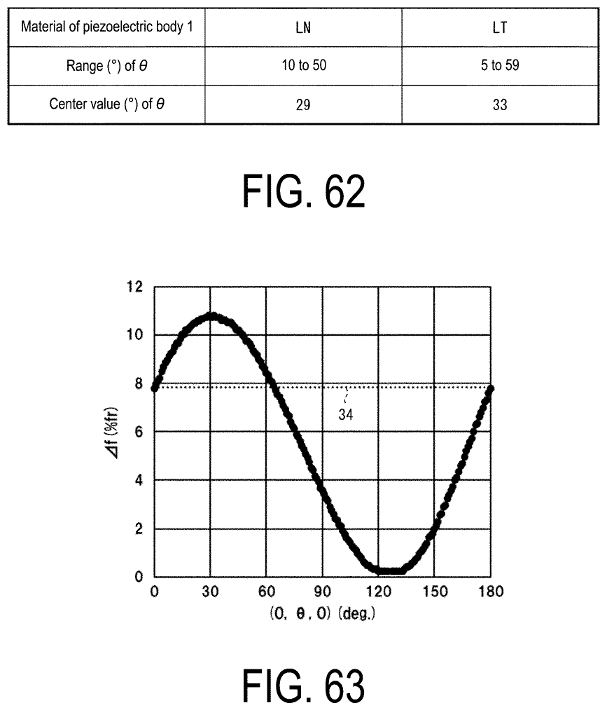

FIG. 62 is a table summarizing advantageous configurations of θ in the back surface embedding. In a case where the piezoelectric body 1 is made of LT in the back surface embedding, when the Euler angles of the piezoelectric body 1 are (0°, θ, 0°), θ may be in the range of 5 to 59°. In a case where the piezoelectric body 1 is made of LN in the back surface embedding, when the Euler angles of the piezoelectric body 1 are (0°, θ, 0°), θ may be in the range of 10 to 50°.

In order to set Δf to a sufficiently large value, the difference between θ and the center value may be in the range of 10° or less. In the back surface embedding in which the material of the piezoelectric body 1 is LT, θ may be in the range of 23 to 43°. In the back surface embedding in which the material of the piezoelectric body 1 is LN, θ may be in the range of 19 to 39°.

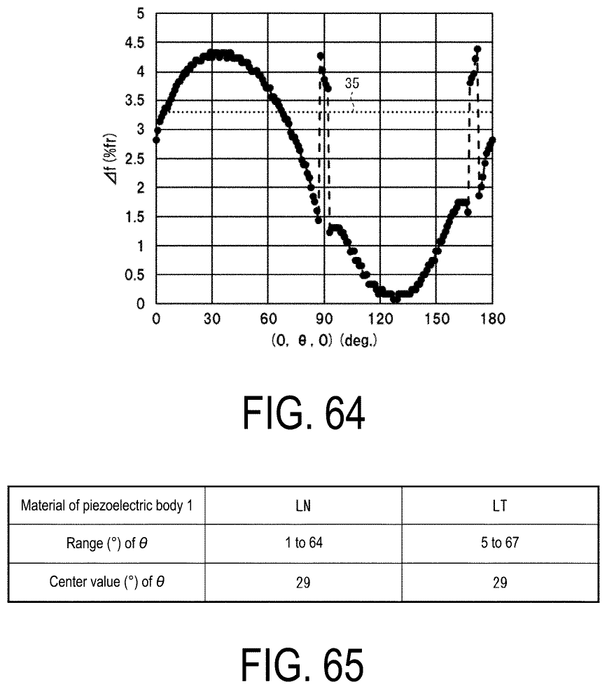

FIG. 63 is a graph showing the relationship of Δf shown on the vertical axis and expressed in units of % fr with respect to θ shown on the horizontal axis and expressed in units of deg in the full surface embedding in which the material of the piezoelectric body 1 is LN. FIG. 64 is a graph showing the relationship of Δf shown on the vertical axis and expressed in units of % fr with respect to θ shown on the horizontal axis and expressed in units of deg in the full surface embedding in which the material of the piezoelectric body 1 is LT.

In the full surface embedding in which the material of the piezoelectric body 1 is LN, the condition of θ in which Δf is above the dotted line 34 was confirmed to be from 1° to 64°. In the full surface embedding in which the material of the piezoelectric body 1 is LT, the condition of θ in which Δf is stably above the dotted line 35 was confirmed to be from 5° to 67°.

FIG. 65 is a table summarizing advantageous configurations of θ in the full surface embedding. In a case where the piezoelectric body 1 is made of LT in the full surface embedding, when the Euler angles of the piezoelectric body 1 are (0°, θ, 0°), θ may be in the range of 5 to 67°. In a case where the piezoelectric body 1 is made of LN in the full surface embedding, when the Euler angles of the piezoelectric body 1 are (0°, θ, 0°), θ may be in the range of 1 to 64°.

In order to set Δf to a sufficiently large value, the difference between θ and the center value may be in the range of 10° or less. In the full surface embedding in which the material of the piezoelectric body 1 is LT, θ may be in the range of 19 to 39°. In the full surface embedding in which the material of the piezoelectric body 1 is LN, θ may be in the range of 19 to 39°.

### CONCLUSION

It can be interpreted that an elastic wave device according to the present disclosure includes the piezoelectric body 1 and the electrode 2 and uses a Lamb wave, at least a part of the electrode 2 being embedded in the piezoelectric body 1.

On the other hand, it can also be interpreted that the elastic wave device according to the present disclosure includes the piezoelectric body 1 and the electrode 2, the piezoelectric body 1 is formed with the groove 1g, the electrode 2 is an IDT electrode and includes the electrode finger 2f, and at least a part of the electrode finger 2f is located inside the groove 1g.

The present disclosure is not limited to each of the embodiments described above, and various modifications can be made within the scope indicated by the claims, and an embodiment obtained by appropriately combining technical means disclosed in different embodiments is also included in the technical scope of the present disclosure.

### REFERENCE SIGNS

1 Piezoelectric body
1g Groove
2 Electrode
2a First layer
2b Second layer
2f Electrode finger
3 Protective film
4 Multilayer film
4a Low acoustic impedance layer
4b High acoustic impedance layer
5 Support substrate
101 Elastic wave device

1. An elastic wave device using a Lamb wave, comprising:
a piezoelectric body and an electrode, wherein
at least a part of the electrode is embedded in the piezoelectric body.

2. An elastic wave device comprising:
a piezoelectric body and an electrode, wherein
the piezoelectric body is formed with a groove,
the electrode is an IDT electrode and comprises an electrode finger, and
at least a part of the electrode finger is located inside the groove.

3. The elastic wave device according to claim 2, wherein an A₁ mode being an antisymmetric mode is used.

4. The elastic wave device according to claim 2, wherein
the piezoelectric body is made of lithium tantalate or lithium niobate,
when the piezoelectric body is lithium tantalate, a frequency f obtained by Equations 1 to 5 is 3 GHz or more, and
when the piezoelectric body is lithium niobate, a frequency f obtained by Equations 1 to 4 and Equation 6 is 3 GHz or more.
$$( Equation 1 )$$
$$\frac{{( {( \frac{2 π}{2 P} )}^{2} - {β}^{2} )}^{2}}{α} sin ( α \times \frac{t Piezo}{2} ) cos ( β \times \frac{t Piezo}{2} ) + 4 {( \frac{2 π}{2 P} )}^{2} β sin ( β \times \frac{t Piezo}{2} ) cos ( α \times \frac{t Piezo}{2} ) = 0 \qquad ( 1 )$$
$$( Equation 2 )$$
$$α = \sqrt{{( \frac{2 π f}{A} )}^{2} - {( \frac{2 π}{2 P} )}^{2}} \qquad ( 2 )$$
$$( Equation 3 )$$
$$β = \sqrt{{( \frac{2 π f}{B} )}^{2} - {( \frac{2 π}{2 P} )}^{2}} \qquad ( 3 )$$
$$( Equation 4 )$$
$$B = ( {b}_{1} \times t Piezo + {b}_{2} ) ( \frac{1}{P} ) + ( {b}_{2} \times t Piezo + {b}_{4} ) \qquad ( 4 )$$
$$( Equation 5 )$$
$$A = 6500 m / s \qquad ( 5 )$$
$$( Equation 6 )$$
$$A = 6550 m / s \qquad ( 6 )$$
where tPiezo is a thickness of the piezoelectric body with a unit m
P is a pitch of a plurality of the electrodes with a unit m
when the piezoelectric body is made of lithium tantalate,
b₁=−1015 m/s
b₂=2.201×10⁻⁴ m²/s
b₃=2.345×10⁹/s
b₄=3001 m/s, and
when the piezoelectric body is made of lithium niobate,
b₁=−950 m/s
b₂=3.979×10⁻⁴ m²/s
b₃=3.456×10⁹/s
b₄=2340 m/s

5. The elastic wave device according to claim 2, wherein
the piezoelectric body is made of lithium tantalate, and
when Euler angles of the piezoelectric body are (φ, θ, ψ), φ is in a range of −23 to 23°, θ is in a range of 1 to 69°, and ψ is in a range of −42 to 42°.

6. The elastic wave device according to claim 2, wherein
the piezoelectric body is made of lithium niobate, and
when Euler angles of the piezoelectric body are (φ, θ, ψ), φ is in a range of −17 to 17°, θ is in a range of 1 to 78°, and ψ is in a range of −21 to 21°.

7. The elastic wave device according to claim 2, wherein the electrode comprises aluminum.

8. The elastic wave device according to claim 2, wherein an upper surface of the electrode is flush with an upper surface of the piezoelectric body.

9. The elastic wave device according to claim 2, wherein an upper end of the electrode comprises a highest portion that is a highest position in the electrode in an upright state of the elastic wave device, and a semi-high portion lower than the highest portion.

10. The elastic wave device according to claim 9, wherein
the upper end of the electrode is rounded, and
the upper end of the electrode and an upper end of the piezoelectric body are connectable by a smooth line.

11. The elastic wave device according to claim 2, wherein a side surface of the electrode is in contact with the piezoelectric body.

12. The elastic wave device according to claim 2, wherein the electrode has a layered structure of a plurality of layers.

13. The elastic wave device according to claim 12, wherein a side surface of an uppermost layer of the plurality of layers is in contact with the piezoelectric body.

14. The elastic wave device according to claim 12, wherein
the plurality of layers comprise a first layer and a second layer disposed on the first layer, and
the first layer is in contact with a side surface of the second layer.

15. The elastic wave device according to claim 2, further comprising a protective film covering the piezoelectric body and the electrode.

16. The elastic wave device according to claim 2, further comprising a multilayer film disposed under the piezoelectric body and the electrode.

17. The elastic wave device according to claim 16, wherein the multilayer film comprises:
a low acoustic impedance layer comprising SiO₂; and
a high acoustic impedance layer comprising at least one selected from the group consisting of HfO₂, Ta₂O₅, and ZrO₂.

18. The elastic wave device according to claim 2, wherein the elastic wave device has a membrane structure.

19. The elastic wave device according to claim 2, wherein a thickness of the piezoelectric body is 1.5 times or more a pitch of a plurality of the electrodes.

20. The elastic wave device according to claim 2, wherein an upper surface of the electrode protrudes with respect to an upper surface of the piezoelectric body.

21. The elastic wave device according to claim 2, wherein an upper surface of the electrode is recessed with respect to an upper surface of the piezoelectric body.

22. The elastic wave device according to claim 21, wherein
the piezoelectric body is made of lithium tantalate, and
when a thickness of the electrode is a, a thickness of the piezoelectric body is b, and a distance between an upper end of the electrode and an upper end of the piezoelectric body along a thickness direction of the piezoelectric body is c, 100×c/(b−a)≤36 is satisfied.

23. The elastic wave device according to claim 21, wherein
the piezoelectric body is made of lithium niobate, and
when a thickness of the electrode is a, a thickness of the piezoelectric body is b, and a distance between an upper end of the electrode and an upper end of the piezoelectric body along a thickness direction of the piezoelectric body is c, 100×c/(b−a)≤69 is satisfied.

24. The elastic wave device according to claim 2, wherein
the piezoelectric body is made of lithium tantalate, and
a thickness of the electrode is 0.2% or more of a thickness of the piezoelectric body and is 161% or less of the thickness of the piezoelectric body.

25. The elastic wave device according to claim 2, wherein
the piezoelectric body is made of lithium tantalate, and
a thickness of the electrode is 20 nm or more and is 161% or less of a thickness of the piezoelectric body.

26. The elastic wave device according to claim 2, wherein
the piezoelectric body is made of lithium niobate, and
a thickness of the electrode is 3% or more of a thickness of the piezoelectric body and is 124% or less of the thickness of the piezoelectric body.

27. The elastic wave device according to claim 2, wherein
the piezoelectric body is made of lithium niobate, and
a thickness of the electrode is 20 nm or more and is 124% or less of a thickness of the piezoelectric body.

28. The elastic wave device according to claim 2, wherein
the piezoelectric body is made of lithium tantalate, and
Duty is from 0.01 to 0.76.

29. The elastic wave device according to claim 1, wherein
the piezoelectric body is made of lithium tantalate,
a width of an electrode finger of the electrode is 0.3 μm or more, and
Duty is 0.76 or less.

30. The elastic wave device according to claim 2, wherein
the piezoelectric body is made of lithium tantalate,
a width of the electrode finger is 0.3 μm or more, and
Duty is 0.76 or less.

31. The elastic wave device according to claim 2, wherein the piezoelectric body is made of lithium niobate, and
Duty is from 0.01 to 0.74.

32. The elastic wave device according to claim 1, wherein
the piezoelectric body is made of lithium niobate,
a width of an electrode finger of the electrode is 0.3 μm or more, and
Duty is 0.74 or less.

33. The elastic wave device according to claim 2, wherein
the piezoelectric body is made of lithium niobate,
a width of the electrode finger is 0.3 μm or more, and
Duty is 0.74 or less.

34. The elastic wave device according to claim 2, wherein a bottom surface of surfaces of the electrode is not in contact with the piezoelectric body, and an entire surface other than the bottom surface is in contact with the piezoelectric body.

35. The elastic wave device according to claim 34, wherein
the piezoelectric body is made of lithium tantalate, and
when Euler angles of the piezoelectric body are (0°, θ, 0°), θ is in a range of 5 to 59°.

36. The elastic wave device according to claim 35, wherein θ is in a range of 23 to 43°.

37. The elastic wave device according to claim 34, wherein
the piezoelectric body is made of lithium niobate, and
when Euler angles of the piezoelectric body are (0°, θ, 0°), θ is in a range of 10 to 50°.

38. The elastic wave device according to claim 37, wherein θ is in a range of 19 to 39°.

39. The elastic wave device according to claim 2, wherein an entire surface of the electrode is in contact with the piezoelectric body.

40. The elastic wave device according to claim 39, wherein
the piezoelectric body is made of lithium tantalate, and
when Euler angles of the piezoelectric body are (0°, θ, 0°), θ is in a range of 5 to 67°.

41. The elastic wave device according to claim 39, wherein
the piezoelectric body is made of lithium niobate, and
when Euler angles of the piezoelectric body are (0°, θ, 0°), θ is in a range of 1 to 64°.

42. The elastic wave device according to claim 40, wherein θ is in a range of 19 to 39°.

43. A communication apparatus comprising the elastic wave device according to claim 2.
